(19) United States
(12) Patent Application Publication
(10) Pub. No.: US 2024/0128319 A1
(43) Pub. Date: Apr. 18, 2024

(54) INTEGRATED CIRCUIT DEVICE

(71) Applicant: Samsung Electronics Co., Ltd., Suwon-si (KR)

(72) Inventors: Hyunwoo KIM, Suwon-si (KR); Wandon KIM, Suwon-si (KR); Jaeseoung PARK, Suwon-si (KR); Hyunbae LEE, Suwon-si (KR); Jeonghyuk YIM, Suwon-si (KR)

(73) Assignee: Samsung Electronics Co., Ltd., Suwon-si (KR)

(21) Appl. No.: 18/322,234

(22) Filed: May 23, 2023

(30) Foreign Application Priority Data
Oct. 14, 2022 (KR) 10-2022-0132716

(51) Int. Cl. H01L 29/06; H01L 27/092; H01L 29/417; H01L 29/423; H01L 29/49; H01L 29/51; H01L 29/775; H01L 29/786

(52) U.S. Cl. CPC H01L 29/0673; H01L 27/092; H01L 29/41733; H01L 29/42392; H01L 29/495; H01L 29/518; H01L 29/775; H01L 29/78696

(57) ABSTRACT

An integrated circuit device includes a first conductive pattern on a substrate, a second conductive pattern surrounding at least a portion of the first conductive pattern and covering a lower portion of a sidewall of the first conductive pattern, an upper insulating structure on the first conductive pattern and the second conductive pattern, and an upper conductive pattern extending in a vertical direction through the upper insulating structure. The upper conductive pattern includes a main plug portion overlapping the first conductive pattern and the second conductive pattern in the vertical direction, and a vertical extension portion extending from a local region of the main plug portion toward the substrate, the vertical extension portion covering an upper portion of the sidewall of the first conductive pattern and overlapping the second conductive pattern in the vertical direction.

### CROSS-REFERENCE TO RELATED APPLICATION

This application is based on and claims priority under 35 U.S.C. §119 to Korean Patent Application No. 10-2022-0132716, filed on Oct. 14, 2022, in the Korean Intellectual Property Office, the disclosure of which is incorporated by reference herein in its entirety.

### BACKGROUND

Various example embodiments relate to an integrated circuit device, and more particularly, to an integrated circuit device including a metal wiring layer.

Due to the advancement of electronics technology, semiconductor devices have been rapidly down-scaled, and thus, linewidths and/or pitches of metal wiring layers in semiconductor devices also have been fine-sized. Therefore, there is a need or desire for an integrated circuit device including a metal wiring structure capable of suppressing or reducing an increase in the resistance of metal wiring layers and/or improving either or both of the electrical characteristics and reliability of the integrated circuit device.

### SUMMARY

Various example embodiments provide an integrated circuit device including a metal wiring structure capable of suppressing or reducing an increase in the resistance of metal wiring layers and improving either or both of the electrical characteristics and reliability of the integrated circuit device.

According to an various example embodiments, there is provided an integrated circuit device including a first conductive pattern on a substrate, a second conductive pattern surrounding at least a portion of the first conductive pattern and covering a lower portion of a sidewall of the first conductive pattern, an upper insulating structure on the first conductive pattern and the second conductive pattern, and an upper conductive pattern extending in a vertical direction through the upper insulating structure. The upper conductive pattern includes a main plug portion overlapping the first conductive pattern and the second conductive pattern in the vertical direction, and a vertical extension portion extending from a local region of the main plug portion toward the substrate. The vertical extension portion covers an upper portion of the sidewall of the first conductive pattern and overlaps the second conductive pattern in the vertical direction.

Alternatively or additionally, according to various example embodiments, there is provided an integrated circuit device including a fin-type active region protruding upward from a substrate, a source/drain region on the fin-type active region, a gate line on the fin-type active region and extending in a direction intersecting the fin-type active region, an insulating structure on the source/drain region, a source/drain contact passing through the insulating structure in the vertical direction and connected to the source/drain region, an upper insulating structure on each of the source/drain contact and the gate line, a first upper conductive pattern passing through the upper insulating structure in the vertical direction and connected to the source/drain contact, and a second upper conductive pattern passing through the upper insulating structure in the vertical direction and be connected to the gate line. At least one of the source/drain contact and the gate line includes a first conductive pattern and a second conductive pattern, the second conductive pattern surrounding at least a portion of the first conductive pattern and covering a lower portion of a sidewall of the first conductive pattern, At least one of the first upper conductive pattern and the second upper conductive pattern includes a main plug portion overlapping the first conductive pattern and the second conductive pattern in the vertical direction, and a vertical extension portion extending from a local region of the main plug portion toward the substrate, the vertical extension portion covering an upper portion of the sidewall of the first conductive pattern and overlapping the second conductive pattern in the vertical direction.

Alternatively or additionally, according to various example embodiments, there is provided an integrated circuit device including a fin-type active region extending lengthwise in a first horizontal direction on a substrate, at least one nanosheet over the fin-type active region, a source/drain region facing the at least one nanosheet in the first horizontal direction, a gate line arranged on the fin-type active region surrounding the at least one nanosheet and extending lengthwise in a second horizontal direction that intersects the first horizontal direction, a source/drain contact connected to the source/drain region, a via contact connected to the source/drain contact, and a gate contact connected to the gate line. The source/drain contact includes a contact plug and a conductive barrier pattern that surrounds a portion of the contact plug and covers a lower portion of a sidewall of the contact plug. The via contact includes a first main plug portion, which overlaps the contact plug and the conductive barrier pattern in the vertical direction, and a first vertical extension portion extending from a local region of the first main plug portion toward the substrate, the first vertical extension portion covering an upper portion of the sidewall of the contact plug and overlapping the conductive barrier pattern in the vertical direction.

### BRIEF DESCRIPTION OF THE DRAWINGS

Various example embodiments will be more clearly understood from the following detailed description taken in conjunction with the accompanying drawings in which:

FIG. 1 is a planar layout diagram illustrating an integrated circuit device according to some example embodiments;

FIG. 2A is a cross-sectional view of the integrated circuit device, taken along a line X1-X1′ of FIG. 1;

FIG. 2B is a cross-sectional view of the integrated circuit device, taken along a line Y1-Y1′ of FIG. 1;

FIG. 3A is an enlarged cross-sectional view of a region EX1 of FIG. 2A;

FIG. 3B is an enlarged cross-sectional view of a region EX2 of FIG. 2A;

FIG. 4 is a cross-sectional view illustrating an integrated circuit device according to some example embodiments;

FIG. 5 is a cross-sectional view illustrating an integrated circuit device according to some example embodiments;

FIG. 6 is a planar layout diagram illustrating an integrated circuit device according to some example embodiments;

FIG. 7A is a cross-sectional view illustrating some components in a cross-section taken along a line X3-X3′ of FIG. 6;

FIG. 7B is a cross-sectional view illustrating some components in a cross-section taken along a line Y3-Y3′ of FIG. 6;

FIG. 7C is an enlarged cross-sectional view of a region EX3 of FIG. 7A;

FIG. 8 is a cross-sectional view illustrating main components of an integrated circuit device according to some example embodiments;

FIGS. 9A to 19 are cross-sectional views respectively illustrating a sequence of processes of a method of fabricating an integrated circuit device, according to some example embodiments, and in particular, FIGS. 9A, 10A, 11A, and 12 to 19 are cross-sectional views respectively illustrating examples of cross-sectional structures in a region corresponding to a cross-section taken along the line X1-X1′ of FIG. 1 according to the sequence of processes, and FIGS. 9B, 10B, and 11B are cross-sectional views respectively illustrating examples of cross-sectional structures in a region corresponding to a cross-section taken along the line Y1-Y1′ of FIG. 1 according to the sequence of processes;

FIGS. 20A to 20C are cross-sectional views respectively illustrating a sequence of example processes of forming a via contact by a method of fabricating an integrated circuit device, according to some example embodiments; and

FIGS. 21A to 21C are cross-sectional views respectively illustrating a sequence of example processes of forming a gate contact by a method of fabricating an integrated circuit device, according to some example embodiments.

### DETAILED DESCRIPTION OF EXAMPLE EMBODIMENTS

Hereinafter, various example embodiments will be described in detail with reference to the accompanying drawings. Like components are denoted by like reference numerals throughout the specification, and repeated descriptions thereof are omitted.

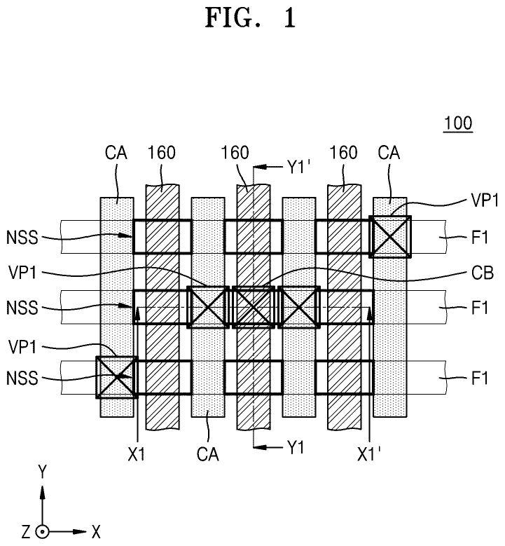

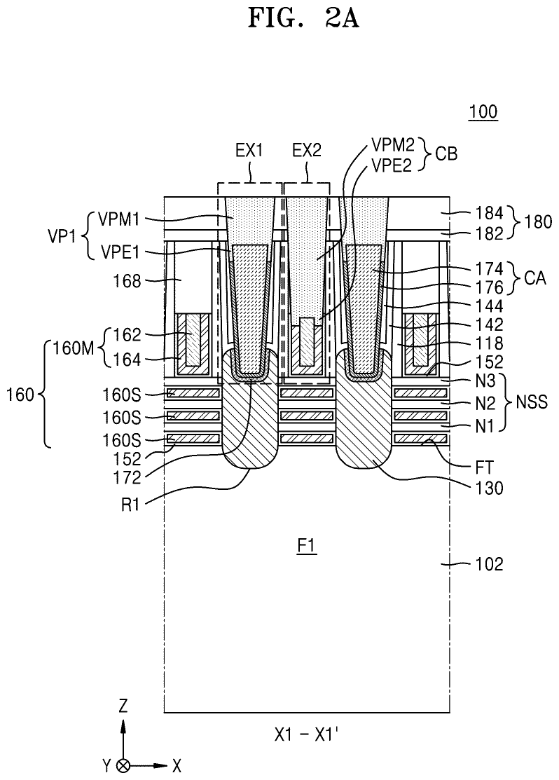

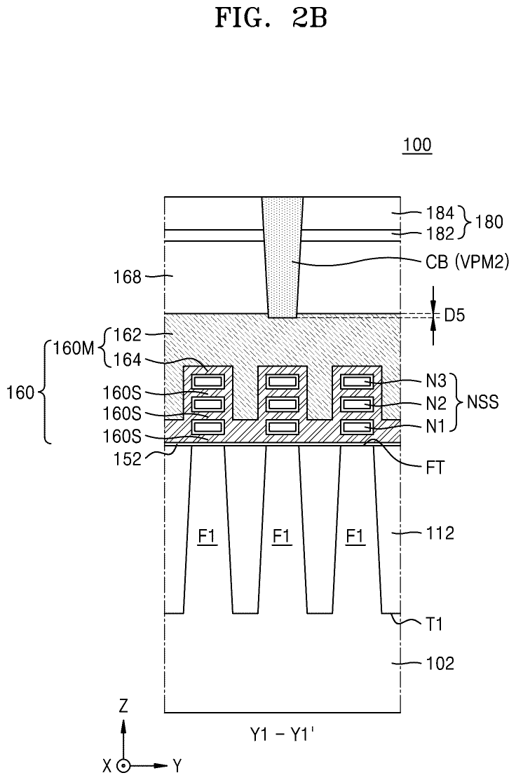

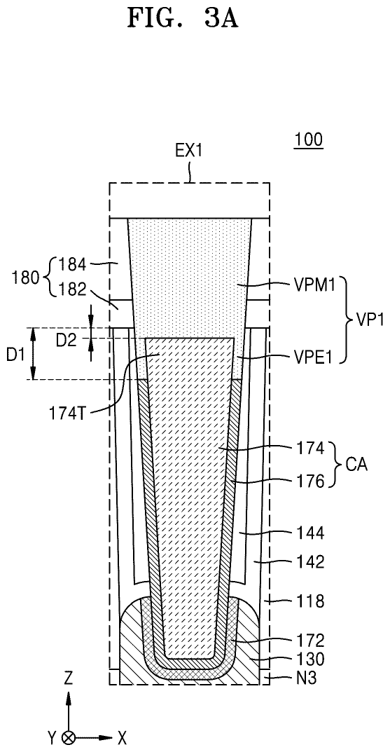

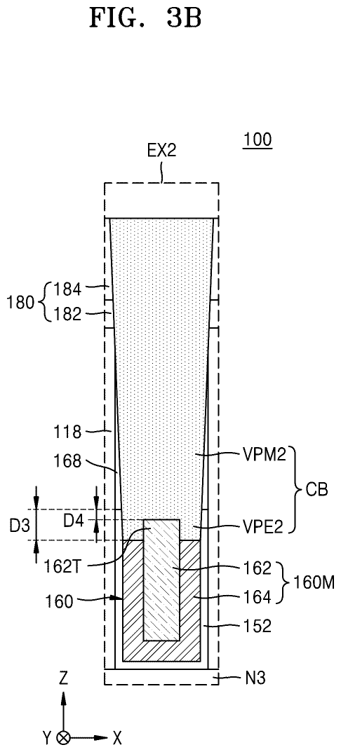

FIG. 1 is a planar layout diagram illustrating an integrated circuit device 100 according to some example embodiments. FIG. 2A is a cross-sectional view of the integrated circuit device 100, taken along a line X1-X1′ of FIG. 1. FIG. 2B is a cross-sectional view of the integrated circuit device 100, taken along a line Y1-Y1′ of FIG. 1. FIG. 3A is an enlarged cross-sectional view of a region EX1 of FIG. 2A. FIG. 3B is an enlarged cross-sectional view of a region EX2 of FIG. 2A. The integrated circuit device 100 including a field effect transistor having a gate-all-around structure, which includes an active region with a nanowire and/or nanosheet shape and a gate surrounding the active region, is described with reference to FIGS. 1 to 3B. The integrated circuit device 100 may include a multi-bridge channel field effect transistor (MBCFET™); however, example embodiments are not limited thereto.

Referring to FIGS. 1 to 3B, the integrated circuit device 100 may include a plurality of fin-type active regions F1, which protrude from a substrate 102 and extend lengthwise in a first horizontal direction (X direction), and a plurality of nanosheet stacks NSS, which face a fin top surface FT of each of the plurality of fin-type active regions F1 while upwardly spaced apart from the plurality of fin-type active regions F1 in a vertical direction (Z direction). As used herein, the term “nanosheet” refers to a conductive structure having a cross-section that is substantially perpendicular to a current-flowing direction. The nanosheet may be understood as including a nanowire.

A trench T1 is formed in the substrate 102 to define the plurality of fin-type active regions F1, and the trench T1 may be filled with a device isolation film 112. The substrate 102 may be or may include a semiconductor, such as Si and/or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not necessarily a chemical formula representing a stoichiometric relationship. The substrate 102 may include a conductive region, for example, an impurity-doped well and/or an impurity-doped structure. The device isolation film 112 may include an oxide film such as a shallow trench isolation (STI) oxide film, a nitride film, or a combination thereof.

A plurality of gate lines 160 may be arranged on the plurality of fin-type active regions F1. Each of the plurality of gate lines 160 may extend lengthwise in a second horizontal direction (Y direction) that intersects the first horizontal direction (X direction).

In intersection areas between the plurality of fin-type active regions F1 and the plurality of gate lines 160, the plurality of nanosheet stacks NSS may be arranged over the fin top surface FT of each of the plurality of fin-type active regions F1. Each of the plurality of nanosheet stacks NSS may include at least one nanosheet arranged apart from the fin top surface FT of the fin-type active region F1 in the vertical direction (Z direction) to face the fin top surface FT of the fin-type active region F1.

As shown in FIGS. 2A and 2B, each of the plurality of nanosheet stacks NSS may include a first nanosheet N1, a second nanosheet N2, and a third nanosheet N3, which overlap each other in the vertical direction (Z direction), and are arranged over the fin-type active region F1. The first nanosheet N1, the second nanosheet N2, and the third nanosheet N3 may respectively have different vertical distances (Z-direction distances) from the fin top surface FT of the fin-type active region F1. Each of the plurality of gate lines 160 may surround the first nanosheet N1, the second nanosheet N2, and the third nanosheet N3, which are included in a nanosheet stack NSS and overlapping each other in the vertical direction (Z direction).

Although FIG. 1 illustrates an example in which a planar shape of the nanosheet stack NSS is approximately quadrangular, example embodiments are not limited thereto. The nanosheet stack NSS may have various planar shapes depending upon respective planar shapes of the fin-type active region F1 and a gate line 160. In some examples, it may be illustrated that the plurality of nanosheet stacks NSS and the plurality of gate lines 160 are arranged on one fin-type active region F1, and that the plurality of nanosheet stacks NSS are arranged in a line in the first horizontal direction (X direction) over the one fin-type active region F1. However, respective numbers of nanosheet stacks NSS and gate lines 160 arranged on one fin-type active region F1 are not particularly limited.

Each of the first nanosheet N1, the second nanosheet N2, and the third nanosheet N3, which are included in the nanosheet stack NSS, may function as a channel region. In some example embodiments, each of the first nanosheet N1, the second nanosheet N2, and the third nanosheet N3 may have, but is not limited to, a thickness selected from a range of about 4 nm to about 6 nm. Here, the thickness of each of the first nanosheet N1, the second nanosheet N2, and the third nanosheet N3 refers to a size in the vertical direction (Z direction). In some example embodiments, the first nanosheet N1, the second nanosheet N2, and the third nanosheet N3 may have substantially the same thickness in the vertical direction (Z direction). In some example embodiments, one or more of the first nanosheet N1, the second nanosheet N2, and the third nanosheet N3 may have a different thickness from others in the vertical direction (Z direction).

As shown in FIG. 2A, the first nanosheet N1, the second nanosheet N2, and the third nanosheet N3, which are included in one nanosheet stack NSS, may have equal or similar sizes to each other in the first horizontal direction (X direction). In some example embodiments, unlike the example shown in FIG. 2A, one or more of the first nanosheet N1, the second nanosheet N2, and the third nanosheet N3, which are included in one nanosheet stack NSS, may have a different size from others in the first horizontal direction (X direction). Additionally or alternatively, although three nanosheets N1, N2, and N3 are illustrated, example embodiments are not limited thereto, and there may be more or fewer than three nanosheets in some example embodiments.

As shown in FIGS. 2A and 2B, each of the plurality of gate lines 160 may include a main gate portion 160M and a plurality of sub-gate portions 160S. The main gate portion 160M may extend lengthwise in the second horizontal direction (Y direction) to cover an upper surface of the nanosheet stack NSS. The plurality of sub-gate portions 160S may be connected, e.g. integrally connected to the main gate portion 160M and may be respectively arranged one by one between the first nanosheet N1, the second nanosheet N2, and the third nanosheet N3 and between the first nanosheet N1 and the fin-type active region F1. In the vertical direction (Z direction), the thickness of each of the plurality of sub-gate portions 160S may be less than the thickness of the main gate portion 160M. Each of the plurality of sub-gate portions 160S may have the same thickness, or at least one of the plurality of sub-gate portions 160S may have a thickness different (e.g. greater than or less than) another one of the plurality of sub-gate portions 160S.

As shown in FIG. 2A, a plurality of recesses R1 may be formed in the fin-type active region F1. A vertical level of a lowermost surface of each of the plurality of recesses R1 may be lower than a vertical level of the fin top surface FT of the fin-type active region F1. As used herein, the term “vertical level” refers to a distance in the vertical direction (Z direction or −Z direction) from a main surface 102M of the substrate 102.

As shown in FIG. 2A, a plurality of source/drain regions 130 may be respectively arranged in the plurality of recesses R1. Each of the plurality of source/drain regions 130 may be arranged adjacent to at least one gate line 160 selected from the plurality of gate lines 160. Each of the plurality of source/drain regions 130 may have surfaces respectively facing the first nanosheet N1, the second nanosheet N2, and the third nanosheet N3, which are included in the nanosheet stack NSS adjacent thereto. Each of the plurality of source/drain regions 130 may be in contact with (e.g. in direct contact with) the first nanosheet N1, the second nanosheet N2, and the third nanosheet N3, which are included in the nanosheet stack NSS adjacent thereto.

Each of the plurality of gate lines 160 may include a metal, a metal nitride, a metal carbide, or a combination thereof, and may or may not include the same material. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. However, a material constituting the plurality of gate lines 160 is not limited to the examples set forth above.

In some example embodiments, each of the plurality of gate lines 160 may include a first work function metal-containing film 162 and a second work function metal-containing film 164. The first work function metal-containing film 162 may include portions at higher vertical levels than a vertical level of the upper surface of the nanosheet stack NSS. The second work function metal-containing film 164 may include portions arranged between the first nanosheet N1, the second nanosheet N2, and the third nanosheet N3 and between the first nanosheet N1 and the fin-type active region F1, and portions at higher vertical levels than the vertical level of the upper surface of the nanosheet stack NSS. Although not shown, the first work function metal-containing film 162 may include portions arranged between the first nanosheet N1, the second nanosheet N2, and the third nanosheet N3 and between the first nanosheet N1 and the fin-type active region F1.

At a higher vertical level than (or more above) the vertical level of the upper surface of the nanosheet stack NSS, the second work function metal-containing film 164 may surround a portion of the first work function metal-containing film 162 and may cover a lower portion of a sidewall of the first work function metal-containing film 162. In some example embodiments, the first work function metal-containing film 162 may include TiN, and the second work function metal-containing film 164 may include TiAlC, but example embodiments are not limited thereto. Herein, the first work function metal-containing film 162 may be referred to as a first conductive pattern, and the second work function metal-containing film 164 may be referred to as a second conductive pattern.

A gate dielectric film 152 may be arranged between the nanosheet stack NSS and the gate line 160. In some example embodiments, the gate dielectric film 152 may include a stack structure of an interface dielectric film and a high-K (high-K dielectric) film. The interface dielectric film may include a low-K material film having a dielectric constant of about 9 or less, for example, a silicon oxide film, a silicon oxynitride film, or a combination thereof. In some example embodiments, the interface dielectric film may be omitted. The high-K film may include a material having a dielectric constant that is greater than that of a silicon oxide film. For example, the high-K film may have a dielectric constant of about 10 to about 25. The high-K film may include, but is not limited to, hafnium oxide.

As shown in FIGS. 2A and 2B, an upper surface of each of the gate dielectric film 152 and the gate line 160 may be covered by a capping insulating pattern 168. The capping insulating pattern 168 may include a silicon nitride film; however, example embodiments are not limited thereto.

Both sidewalls of each of the gate line 160 and the capping insulating pattern 168 may be covered by an outer insulating spacer 118. The outer insulating spacer 118 may be arranged on an upper surface of each of the plurality of nanosheet stacks NSS to cover both sidewalls of the main gate portion 160M. The outer insulating spacer 118 may be apart from the gate line 160 with the gate dielectric film 152 therebetween. The outer insulating spacer 118 may include silicon nitride, silicon oxide, SiCN, SiBN, SiON, SiOCN, SiBCN, SiOC, or a combination thereof. As used herein, each of the terms “SiCN”, “SiBN”, “SiON”, “SiOCN”, “SiBCN”, and “SiOC” refers to a material including elements contained in each term and is not necessarily a chemical formula representing a stoichiometric relationship.

A plurality of outer insulating spacers 118 and the plurality of source/drain regions 130 on the substrate 102 may be covered by an insulating liner 142. The insulating liner 142 may include silicon nitride (SiN), silicon oxide (SiO), SiCN, SiBN, SiON, SiOCN, SiBCN, SiOC, or a combination thereof. In some example embodiments, the insulating liner 142 may be omitted. An inter-gate dielectric 144 may be arranged on the insulating liner 142. The inter-gate dielectric 144 may include a silicon nitride film, a silicon oxide film, SiON, SiOCN, or a combination thereof. When the insulating liner 142 is omitted, the inter-gate dielectric 144 may contact (e.g. directly contact) the plurality of source/drain regions 130.

Either sidewall of each of the plurality of sub-gate portions 160S may be apart from the source/drain region 130 with the gate dielectric film 152 therebetween. The gate dielectric film 152 may be arranged between a sub-gate portion 160S of the gate line 160 and each of the first nanosheet N1, the second nanosheet N2, and the third nanosheet N3 and between the sub-gate portion 160S of the gate line 160 and the source/drain region 130.

In intersection areas between the plurality of fin-type active regions F1 and the plurality of gate lines 160, the plurality of nanosheet stacks NSS may be arranged over the fin top surface FT of each of the plurality of fin-type active regions F1 and may be apart from the fin-type active region F1 to face the fin top surface FT of the fin-type active region F1. A plurality of nanosheet transistors may be respectively formed on the substrate 102 in the intersection areas between the plurality of fin-type active regions F1 and the plurality of gate lines 160.

Although FIG. 1 illustrates an example in which the planar shape of the nanosheet stack NSS is approximately quadrangular, example embodiments are not limited thereto. The nanosheet stack NSS may have various planar shapes depending upon the respective planar shapes of the fin-type active region F1 and the gate line 160. In some example embodiments, it may be illustrated that the plurality of nanosheet stacks NSS and the plurality of gate lines 160 are arranged on one fin-type active region F1, and that the plurality of nanosheet stacks NSS are arranged in a line in the first horizontal direction (X direction) over the one fin-type active region F1. However, according to the inventive concept, the number of nanosheet stacks NSS arranged over one fin-type active region F1 are not particularly limited. For example, one nanosheet stack NSS may be formed over one fin-type active region F1. Although the present example illustrates that each of the plurality of nanosheet stacks NSS includes three nanosheets, example embodiments are not limited thereto. For example, the nanosheet stack NSS may include at least one nanosheet, and the number of nanosheets constituting the nanosheet stack NSS is not particularly limited.

Each of the first nanosheet N1, the second nanosheet N2, and the third nanosheet N3 of the nanosheet stack NSS may have a channel region. In some example embodiments, each of the first nanosheet N1, the second nanosheet N2, and the third nanosheet N3 of the nanosheet stack NSS may include an Si layer, a SiGe layer, or a combination thereof.

A metal silicide film 172 may be formed on an upper surface of each of the plurality of source/drain regions 130. The metal silicide film 172 may include a metal including one or more of Ti, W, Ru, Nb, Mo, Hf, Ni, Co, Pt, Yb, Tb, Dy, Er, or Pd. For example, the metal silicide film 172 may include, but is not limited to, titanium silicide.

The insulating liner 142 and the inter-gate dielectric 144 may be sequentially arranged in the stated order on the plurality of source/drain regions 130 and a plurality of metal silicide films 172. The insulating liner 142 and the inter-gate dielectric 144 may constitute an insulating structure. In some example embodiments, the insulating liner 142 may include, but is not limited to, silicon nitride (SiN), SiCN, SiBN, SiON, SiOCN, SiBCN, or a combination thereof. The inter-gate dielectric 144 may include, but is not limited to, a silicon oxide film.

A plurality of source/drain contacts CA may be respectively arranged on the plurality of source/drain regions 130. Each of the plurality of source/drain contacts CA may pass through the inter-gate dielectric 144 and the insulating liner 142 in the vertical direction (Z direction) and thus be in contact with the metal silicide film 172. Each of the plurality of source/drain contacts CA may be electrically connected, or configured to be electrically connected to the source/drain region 130 through the metal silicide film 172. Each of the plurality of source/drain contacts CA may be apart from the main gate portion 160M in the first horizontal direction (X direction) with the outer insulating spacer 118 therebetween.

Each of the plurality of source/drain contacts CA may include a contact plug 174 and a conductive barrier pattern 176 that surrounds and contacts a lower surface and a sidewall of the contact plug 174. Herein, the contact plug 174 may be referred to as a first conductive pattern, and the conductive barrier pattern 176 may be referred to as a second conductive pattern. In some example embodiments, the contact plug 174 may include a metal selected from among molybdenum (Mo), copper (Cu), tungsten (W), cobalt (Co), ruthenium (Ru), manganese (Mn), titanium (Ti), tantalum (Ta), aluminum (Al), and a combination thereof. The conductive barrier pattern 176 may include a metal or a metal nitride. For example, the conductive barrier pattern 176 may include, but is not limited to, Ti, Ta, W, TiN, TaN, WN, WCN, TiSiN, TaSiN, WSiN, or a combination thereof.

The contact plug 174 may extend lengthwise in the vertical direction (Z direction) through the inter-gate dielectric 144 and the insulating liner 142. The conductive barrier pattern 176 may be arranged between the metal silicide film 172 and the contact plug 174. The conductive barrier pattern 176 may have a surface contacting (e.g. directly contacting) the metal silicide film 172 and a surface contacting the contact plug 174.

As shown in FIGS. 2A and 2B, respective upper surfaces of the plurality of source/drain contacts CA and a plurality of capping insulating patterns 168 may be covered by an upper insulating structure 180. The upper insulating structure 180 may include an etch stop film 182 and an interlayer dielectric 184, which are sequentially stacked in the stated order on the plurality of source/drain contacts CA and the plurality of capping insulating patterns 168. The etch stop film 182 may include silicon carbide (SiC), SiN, nitrogen-doped silicon carbide (SiC:N), SiOC, AN, AlON, AlO, AlOC, or a combination thereof. The interlayer dielectric 184 may include an oxide film, a nitride film, an ultra-low-K film having an ultra-low dielectric constant (that is, K) of about 2.2 to about 2.4, or a combination thereof. For example, the interlayer dielectric 184 may include, but is not limited to, a tetraethyl orthosilicate (TEOS) film, a high-density plasma (HDP) oxide film, a boro-phospho-silicate glass (BPSG) film, a flowable chemical vapor deposition (FCVD) oxide film, an SiON film, an SiN film, an SiOC film, an SiCOH film, or a combination thereof.

As shown in FIGS. 1 and 2A, a plurality of via contacts VP1 may be respectively arranged on the plurality of source/drain contacts CA. Each of the plurality of via contacts VP1 may be in contact with a source/drain contact CA through the upper insulating structure 180. Herein, the via contact VP1 may be referred to as an upper conductive pattern or a first upper conductive pattern. Each of the plurality of source/drain regions 130 may be configured to be electrically connected to the via contact VP1 through the metal silicide film 172 and the source/drain contact CA. A lower surface of each of the plurality of via contacts VP1 may be in contact with the upper surface of the source/drain contact CA. Each of the plurality of via contacts VP1 may include, but is not limited to, molybdenum (Mo) and/or tungsten (W).

As shown in FIGS. 1, 2A, and 2B, a gate contact CB may be arranged on the gate line 160. The gate contact CB may be configured to pass through the upper insulating structure 180 in the vertical direction (Z direction) and thus be connected to the gate line 160. A lower surface of the gate contact CB may be in contact with the upper surface of the gate line 160. Herein, the gate contact CB may be referred to as an upper conductive pattern or a second upper conductive pattern. In some example embodiments, the gate contact CB may include, but is not limited to, molybdenum (Mo) and/or tungsten (W).

As shown in FIGS. 2A and 3A, in an area in which the source/drain contact CA is in contact with the via contact VP1, the conductive barrier pattern 176 may cover a lower portion of a sidewall of the source/drain contact CA. In the area in which the source/drain contact CA is in contact with the via contact VP1, the conductive barrier pattern 176 may surround the lower surface and a portion of the sidewall of the contact plug 174. Under the via contact VP1, the length of the conductive barrier pattern 176 in the vertical direction (Z direction) may be less than the length of the contact plug 174 in the vertical direction (Z direction).

The via contact VP1 may include a main plug portion VPM1, which overlaps each of the contact plug 174 and the conductive barrier pattern 176 in the vertical direction (Z direction), and a vertical extension portion VPE1, which extends from a local region of the main plug portion VPM1 toward the substrate 102. The vertical extension portion VPE1 of the via contact VP1 may cover an upper portion of the sidewall of the contact plug 174 and may overlap the conductive barrier pattern 176 in the vertical direction (Z direction). The main plug portion VPM1 and the vertical extension portion VPE1 of the via contact VP1 may be integrally connected to each other, e.g. may be homogenous with each other, and may include the same material and/or may be formed at the same time. For example, there may not be a seam or an interface between the main plug portion VPM1 and the vertical extension portion VPE1.

Under the via contact VP1, the length from the substrate 102 to an uppermost surface of the contact plug 174 in the vertical direction (Z direction) may be greater than the length from the substrate 102 to an uppermost surface of the conductive barrier pattern 176 in the vertical direction (Z direction). For example, as shown in FIG. 2A, in the vertical direction (Z direction), the length from the fin top surface FT of the fin-type active region F1 to the uppermost surface of the contact plug 174 may be greater than the length from the fin top surface FT of the fin-type active region F1 to the uppermost surface of the conductive barrier pattern 176. As shown in FIG. 3A, the contact plug 174 may include a top portion 174T protruding in a direction away from the substrate 102 more than the conductive barrier pattern 176. The top portion 174T of the contact plug 174 may be accommodated in a space defined by the vertical extension portion VPE1 of the via contact VP1.

The via contact VP1 may be in contact with a portion of each of the contact plug 174 and the conductive barrier pattern 176. The via contact VP1 may include a portion contacting the upper surface of the contact plug 174, a portion contacting the upper surface of the conductive barrier pattern 176, and a portion contacting an upper portion of the sidewall of the contact plug 174, which is not covered by the conductive barrier pattern 176.

In some example embodiments, under the via contact VP1, a vertical level of the uppermost surface of the conductive barrier pattern 176 may be below, e.g. may be lower by a first vertical distance D1 than a vertical level of an uppermost surface of at least one of the insulating liner 142 and the inter-gate dielectric 144. In some example embodiments, under the via contact VP1, a vertical level of the uppermost surface of the contact plug 174 may be below, e.g. may be lower by a second vertical distance D2 than a vertical level of an uppermost surface of at least one of the insulating liner 142 and the inter-gate dielectric 144. The first vertical distance D1 may be greater than the second vertical distance D2.

In some example embodiments, a constituent material of the via contact VP1 may have an electric resistivity or an electrical resistance less than an electric resistivity or electrical resistance of a constituent material of the conductive barrier pattern 176. For example, the via contact VP1 may include molybdenum (Mo) or tungsten (W), and the conductive barrier pattern 176 may include TiN. Because the upper portion of the sidewall of the contact plug 174 is covered by the via contact VP1 having an electric resistance/resistivity less than an electric resistance/resistivity of the conductive barrier pattern 176, contact resistance between the source/drain contact CA and the via contact VP1 may be reduced to improve electrical characteristics, such as speed and/or power consumption, of the integrated circuit device 100.

As shown in FIGS. 2A and 2B, in the gate line 160, the second work function metal-containing film 164 may be closer to the gate dielectric film 152 than the first work function metal-containing film 162 is. The first work function metal-containing film 162 may be apart from the nanosheet stack NSS with the second work function metal-containing film 164 and the gate dielectric film 152 therebetween.

As shown in FIGS. 2A, 2B, and 3B, in an area in which the gate line 160 is in contact with the gate contact CB, the second work function metal-containing film 164 may cover a lower portion of the sidewall of the first work function metal-containing film 162. Between the nanosheet stack NSS and the gate contact CB, the second work function metal-containing film 164 may surround the lower surface and a portion of the sidewall of the first work function metal-containing film 162. Between the nanosheet stack NSS and the gate contact CB, the length of the second work function metal-containing film 164 in the vertical direction (Z direction) may be less than the length of the first work function metal-containing film 162 in the vertical direction (Z direction).

The gate contact CB may include a main plug portion VPM2, which overlaps or at least partially overlaps each of the first work function metal-containing film 162 and the second work function metal-containing film 164 of the gate line 160 in the vertical direction (Z direction), and a vertical extension portion VPE2, which extends from a local region of the main plug portion VPM2 toward the substrate 102. The vertical extension portion VPE2 of the gate contact CB may cover an upper portion of the sidewall of the first work function metal-containing film 162 and overlap the second work function metal-containing film 164 in the vertical direction (Z direction). The main plug portion VPM2 and the vertical extension portion VPE2 of the gate contact CB may be integrally connected to each other and may include the same material.

Under the gate contact CB, the length from the substrate 102 to an uppermost surface of the first work function metal-containing film 162 in the vertical direction (Z direction) may be greater than the length from the substrate 102 to an uppermost surface of the second work function metal-containing film 164 in the vertical direction (Z direction). For example, as shown in FIG. 2B, in the vertical direction (Z direction), the length from the fin top surface FT of the fin-type active region F1 to the uppermost surface of the first work function metal-containing film 162 may be greater than the length from the fin top surface FT of the fin-type active region F1 to the uppermost surface of the second work function metal-containing film 164. As shown in FIG. 3B, the first work function metal-containing film 162 may include a top portion 162T protruding in a direction away from the substrate 102 more than the second work function metal-containing film 164. The top portion 162T of the first work function metal-containing film 162 may be accommodated in a space defined by the vertical extension portion VPE2 of the gate contact CB.

The gate contact CB may be in contact with a portion of each of the first work function metal-containing film 162 and the second work function metal-containing film 164. The gate contact CB may include a portion contacting an upper surface of the first work function metal-containing film 162, a portion contacting an upper surface of the second work function metal-containing film 164, and a portion contacting an upper portion of the sidewall of the first work function metal-containing film 162, which is not covered by the second work function metal-containing film 164.

In some example embodiments, under the gate contact CB, a vertical level of the uppermost surface of the second work function metal-containing film 164 may be below, e.g. may be lower by a third vertical distance D3 than a vertical level of an uppermost surface of the gate dielectric film 152. In some example embodiments, under the gate contact CB, a vertical level of the uppermost surface of the first work function metal-containing film 162 may be below, e.g. may be lower by a fourth vertical distance D4 than the vertical level of the uppermost surface of the gate dielectric film 152. The third vertical distance D3 may be greater than the fourth vertical distance D4. As shown in FIG. 2B, in the upper surface of the first work function metal-containing film 162, a portion covered by the gate contact CB may be lower by a fifth vertical distance D5 than a portion covered by the capping insulating pattern 168. The fifth vertical distance D5 may be equal to or similar to the fourth vertical distance D4.

In some example embodiments, a constituent material of the gate contact CB may have an electric resistance or resistivity less than an electric resistance or resistivity of a constituent material of the second work function metal-containing film 164. For example, the gate contact CB may include molybdenum (Mo) or tungsten (W), and the second work function metal-containing film 164 may include TiAlC. Because the upper portion of the sidewall of the first work function metal-containing film 162 is covered by the gate contact CB having an electric resistance less than an electric resistance of the second work function metal-containing film 164, contact resistance between the gate line 160 and the gate contact CB may be reduced to improve the electrical characteristics, such as speed and/or power consumption, of the integrated circuit device 100.

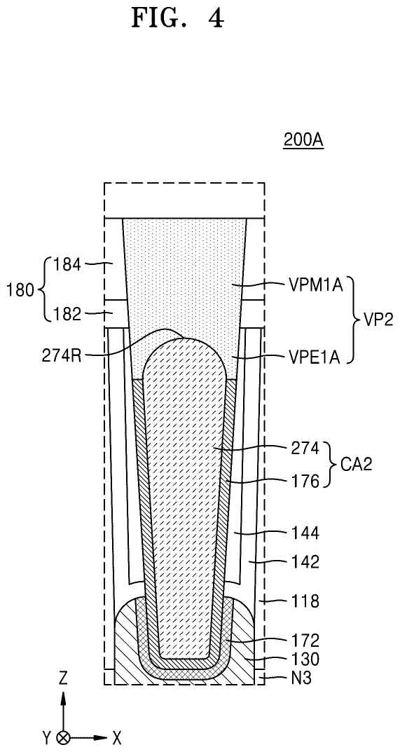

FIG. 4 is a cross-sectional view illustrating an integrated circuit device 200A according to some example embodiments. FIG. 4 illustrates an enlarged cross-sectional configuration of a region of the integrated circuit device 200A, which corresponds to the region EX1 of FIG. 2A. In FIG. 4, the same reference numerals as in FIGS. 1 to 3B respectively denote the same members, and here, repeated descriptions thereof are omitted.

Referring to FIG. 4, the integrated circuit device 200A has substantially the same configuration as the integrated circuit device 100 described with reference to FIGS. 1 to 3B. However, the integrated circuit device 200A includes a source/drain contact CA2 and a via contact VP2 that is arranged on and is connected to the source/drain contact CA2.

The source/drain contact CA2 may include a contact plug 274 and the conductive barrier pattern 176. The via contact VP2 may include a main plug portion VPM1A, which overlaps each of the contact plug 274 and the conductive barrier pattern 176 of the source/drain contact CA2 in the vertical direction (Z direction), and a vertical extension portion VPE1A, which extends from a local region of the main plug portion VPM1A toward the conductive barrier pattern 176.

The contact plug 274 of the source/drain contact CA2 has substantially the same configuration as the contact plug 174 described with reference to FIGS. 2A and 3A. However, the contact plug 274 may have a round upper surface 274R that is convex toward the via contact VP2. In some example embodiments, the contact plug 274 may have a beveled profile in cross-section.

The main plug portion VPM1A and the vertical extension portion VPE1A of the via contact VP2 are substantially the same as described regarding the main plug portion VPM1 and the vertical extension portion VPE1 with reference to FIGS. 2A and 3A, respectively. However, the main plug portion VPM1A may have a surface that is concave toward the contact plug 274 in correspondence with the round upper surface 274R of the contact plug 274.

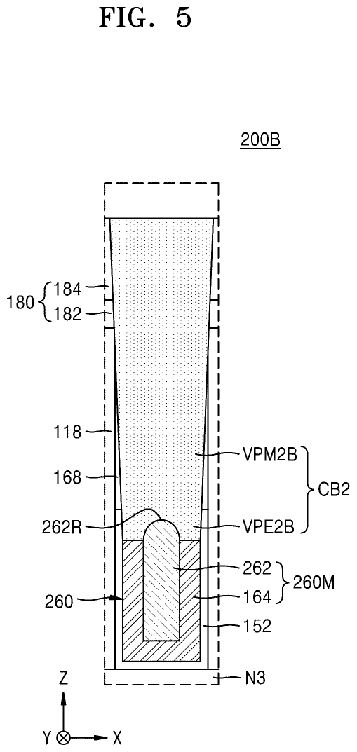

FIG. 5 is a cross-sectional view illustrating an integrated circuit device 200B according to some example embodiments. FIG. 5 illustrates an enlarged cross-sectional configuration of a region of the integrated circuit device 200B, which corresponds to the region EX2 of FIG. 2A. In FIG. 5, the same reference numerals as in FIGS. 1 to 3B respectively denote the same members, and here, repeated descriptions thereof are omitted.

Referring to FIG. 5, the integrated circuit device 200B has substantially the same configuration as the integrated circuit device 100 described with reference to FIGS. 1 to 3B. However, the integrated circuit device 200B includes a gate line 260 including a main gate portion 260M, and a gate contact CB2 arranged on and connected to the gate line 260.

The main gate portion 260M of the gate line 260 may include a first work function metal-containing 262 and the second work function metal-containing 164. The gate contact CB2 may include a main plug portion VPM2B, which overlaps each of the first work function metal-containing 262 and the second work function metal-containing 164 in the vertical direction (Z direction), and a vertical extension portion VPE2B, which extends from a local region of the main plug portion VPM2B toward the second work function metal-containing 164.

The first work function metal-containing 262 of the gate line 260 has substantially the same configuration as the first work function metal-containing 162 described with reference to FIGS. 2A, 2B, and 3B. However, the first work function metal-containing 262 may have a round upper surface 262R that is convex toward the gate contact CB2.

The main plug portion VPM2B and the vertical extension portion VPE2B of the gate contact CB2 are substantially the same as described regarding the main plug portion VPM2 and the vertical extension portion VPE2 with reference to FIGS. 2A, 2B, and 3B, respectively. However, the main plug portion VPM2B may have a surface that is concave upward, e.g. toward the first work function metal-containing 262 in correspondence with the round upper surface 262R of the first work function metal-containing 262.

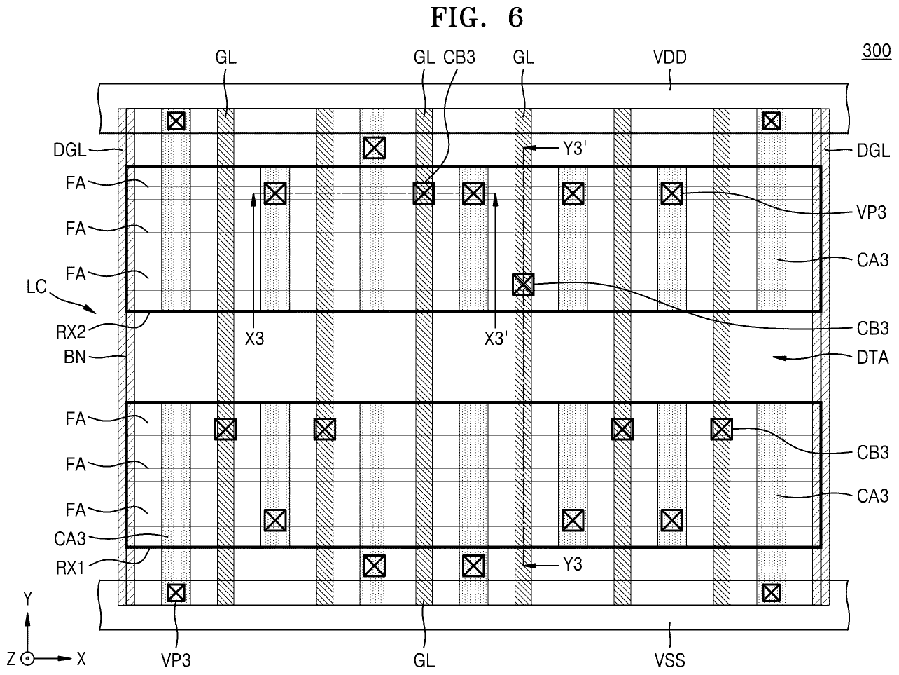

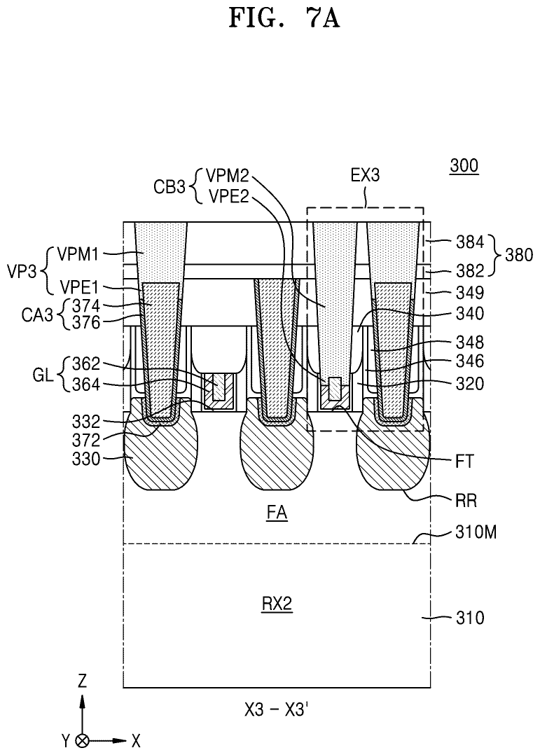

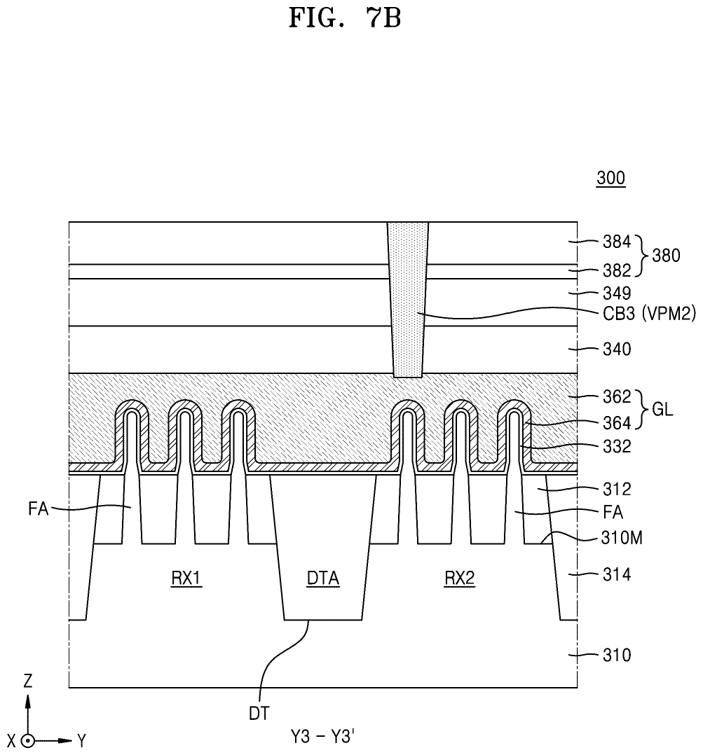

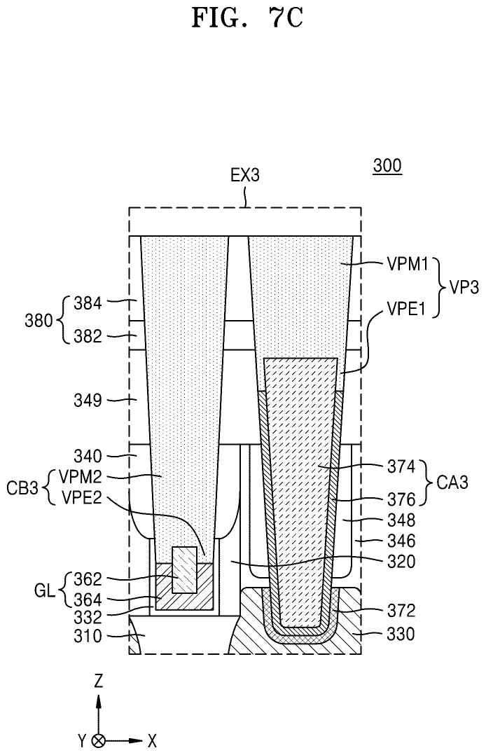

FIG. 6 is a planar layout diagram illustrating an integrated circuit device 300 according to some example embodiments. FIG. 7A is a cross-sectional view illustrating some components in a cross-section taken along a line X3-X3′ of FIG. 6, FIG. 7B is a cross-sectional view illustrating some components in a cross-section taken along a line Y3-Y3′ of FIG. 6, and FIG. 7C is an enlarged cross-sectional view of a region EX3 of FIG. 7A.

Referring to FIGS. 6 and 7A to 7C, the integrated circuit device 300 may include a logic cell including one or more fin field effect transistor (FinFET) devices. The integrated circuit device 300 may include a logic cell LC formed in an area that is defined by a cell boundary BN on a substrate 310.

The substrate 310 may have a main surface 310M extending in a horizontal direction (X-Y plane direction). The substrate 310 may have substantially the same configuration as the substrate 102 described with reference to FIGS. 2A and 2B.

The logic cell LC may include a first device area RX1 and a second device area RX2. A plurality of fin-type active regions FA, which protrude from the substrate 310, may be arranged in each of the first device area RX1 and the second device area RX2. The plurality of fin-type active regions FA may extend parallel to each other in a width direction of the logic cell LC, for example, the first horizontal direction (X direction).

As shown in 7B, a device isolation film 312 may be arranged on the substrate 310 in the first device area RX1 and the second device area RX2. The device isolation film 312 may be arranged between the plurality of fin-type active regions FA and may cover a lower sidewall of each of the plurality of fin-type active regions FA. In the first device area RX1 and the second device area RX2, the plurality of fin-type active regions FA may protrude upward in fin shapes from the device isolation film 312. An inter-device isolation area DTA may be arranged between the first device area RX1 and the second device area RX2. A trench such as a deep trench DT may be formed in the inter-device isolation area DTA to define the first device area RX1 and the second device area RX2, and the deep trench DT may be filled with an inter-device isolation insulating film 314, e.g. with a process such as a chemical vapor deposition (CVD) process. Each of the device isolation film 312 and the inter-device isolation insulating film 314 may include an oxide film.

A plurality of gate dielectric films 332 and a plurality of gate lines GL may extend, on the substrate 310, in a height direction of the logic cell LC, that is, the second horizontal direction (Y direction), the height direction of the logic cell LC being a direction intersecting the plurality of fin-type active regions FA. The plurality of gate dielectric films 332 and the plurality of gate lines GL may cover an upper surface and both sidewalls of each of the plurality of fin-type active regions FA, an upper surface of the device isolation film 312, and an upper surface of the inter-device isolation insulating film 314.

In the first device area RX1 and the second device area RX2, a plurality of MOS transistors may be formed along the plurality of gate lines GL. Each of the plurality of MOS transistors may be or may include a 3-dimensional-structured MOS transistor in which a channel is formed on the upper surface and both sidewalls of each of the plurality of fin-type active regions FA. In some example embodiments, the first device area RX1 may be or may correspond to an NMOS transistor area, and a plurality of NMOS transistors may be respectively formed in intersection regions between the fin-type active region FA and the gate line GL in the first device area RX1. The second device area RX2 may be or may correspond to a PMOS transistor area, and a plurality of PMOS transistors may be respectively formed in intersection regions between the fin-type active region FA and the gate line GL in the second device area RX2. Example embodiments are not limited thereto; for example, the first device area RX1 may be or may correspond to a PMOS transistor area, while the second device area RX2 may be or may correspond to an NMOS transistor area.

A dummy gate line DGL may extend along a portion of the cell boundary BN, which extends in the second horizontal direction (Y direction). The dummy gate line DGL may include the same material as the plurality of gate lines GL. The dummy gate line DGL may be maintained in an electrically floating state during the operation of the integrated circuit device 100, thereby functioning as an electrical isolation area between the logic cell LC and another logic cell around the logic cell LC. The plurality of gate lines GL and a plurality of dummy gate lines DGL may each have the same width in the first horizontal direction (X direction) and may be arranged at regular pitches in the first horizontal direction (X direction).

The plurality of gate dielectric films 332 may each include a silicon oxide film, a high-K film, or a combination thereof. The high-K film may include a material having a greater dielectric constant than a silicon oxide film. The high-K film may include a metal oxide and/or a metal oxynitride. An interface film (not shown) may be arranged between the fin-type active region FA and a gate dielectric film 332. The interface film may include one or more of an oxide film, a nitride film, or an oxynitride film.

The plurality of gate lines GL and the plurality of dummy gate lines DGL may each have a structure in which a metal nitride layer, a metal layer, a conductive capping layer, and a gap-fill metal film are stacked in the stated order. The metal nitride layer and the metal layer may each include at least one metal selected from among titanium (Ti), tantalum (Ta), tungsten (W), ruthenium (Ru), niobium (Nb), molybdenum (Mo), and hafnium (Hf). The gap-fill metal film may include a W film or an Al film. The plurality of gate lines GL and the plurality of dummy gate lines DGL may each include a work function metal-containing layer. The work function metal-containing layer may include at least one metal selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). In some example embodiments, the plurality of gate lines GL and the plurality of dummy gate lines DGL may each include, but are not limited to, a stack structure of TiAlC/TiN/W, a stack structure of TiN/TaN/TiAlC/TiN/W, or a stack structure of TiN/TaN/TiN/TiAlC/TiN/W.

In some example embodiments, each of the plurality of gate lines GL may include a first work function metal-containing film 362 and a second work function metal-containing film 364. More detailed configurations of the first work function metal-containing film 362 and the second work function metal-containing film 364 are respectively the same as described regarding the first work function metal-containing film 162 and the second work function metal-containing film 164 with reference to FIGS. 2A, 2B, and 3B.

A plurality of insulating spacers 320 may each cover both sidewalls of each of the plurality of gate lines GL and the plurality of dummy gate lines DGL. The plurality of gate lines GL, the plurality of dummy gate lines DGL, the plurality of gate dielectric films 332, and the plurality of insulating spacers 320 may be covered by an insulating capping line 340. Each of the insulating capping line 340 and the plurality of insulating spacers 320 may extend in a line shape in the second horizontal direction (Y direction).

Each of the plurality of insulating spacers 320 may include, but is not limited to, silicon nitride (SiN), SiCN, SiBN, SiON, SiOCN, SiBCN, or a combination thereof. A plurality of insulating capping lines 340 may each include SiN.

A plurality of recess regions RR may be formed in an upper surface of each of the plurality of fin-type active regions FA. A plurality of source/drain regions 330 may be respectively arranged in the plurality of recess regions RR. The gate line GL may be apart from a source/drain region 330 with the gate dielectric film 332 and an insulating spacer 320 therebetween.

The plurality of source/drain regions 330 may include epitaxial semiconductor layers, for example, layers that are epitaxially grown, either heterogeneously or homogeneously, on the plurality of recess regions RR, respectively. For example, each of the plurality of source/drain regions 330 may include one or more of an epitaxially grown Si layer, an epitaxially grown SiC layer, or a plurality of epitaxially grown SiGe layers. When the first device area RX1 is an NMOS transistor area and the second device area RX2 is a PMOS transistor area, each of the plurality of source/drain regions 330 in the first device area RX1 may include an Si layer doped with one or more n-type dopants, or an SiC layer doped with one or more n-type dopants, and each of the plurality of source/drain regions 330 in the second device area RX2 may include an SiGe layer doped with one or more p-type dopants. The n-type dopants may be selected from phosphorus (P), arsenic (As), and antimony (Sb). The p-type dopants may be selected from boron (B) and gallium (Ga). In some example embodiments, the PMOS transistor area may be counter-doped with n-type dopants and/or the NMOS transistor area may be counter-doped with p-type dopants; example embodiments are not limited thereto.

In some example embodiments, each of the plurality of source/drain regions 330 in the first device area RX1 may be different in shape and/or in size from each of the plurality of source/drain regions 330 in the second device area RX2. The shape of each of the plurality of source/drain regions 330 is not limited to the example shown in FIGS. 7A and 7C, and the plurality of source/drain regions 330 having various shapes and sizes may be formed in the first device area RX1 and the second device area RX2.

A plurality of metal silicide films 372 may be respectively arranged on the plurality of source/drain regions 330. A metal silicide film 372 may have the same configuration as the metal silicide film 172 described with reference to FIGS. 2A and 3A.

An insulating liner 346 and an inter-gate dielectric 348 may be sequentially arranged in the stated order on the plurality of source/drain regions 330 and the plurality of metal silicide films 372. The insulating liner 346 and the inter-gate dielectric 348 may constitute an insulating structure. In some example embodiments, the insulating liner 346 may include, but is not limited to, silicon nitride (SiN), SiCN, SiBN, SiON, SiOCN, SiBCN, or a combination thereof. The inter-gate dielectric 348 may include, but is not limited to, a silicon oxide film.

A plurality of source/drain contacts CA3 may each be configured to pass through the inter-gate dielectric 348 and the insulating liner 346 in the vertical direction (Z direction) and thus be connected to the source/drain region 330 through the metal silicide film 372. Each of the plurality of source/drain contacts CA3 may be apart from the gate line GL in the first horizontal direction (X direction) with the insulating spacer 320 therebetween. Each of the plurality of source/drain regions 330 may be connected to a via contact VP3 through the metal silicide film 372 and the source/drain contact CA3.

Each of the plurality of source/drain contacts CA3 may include a contact plug 374 and a conductive barrier pattern 376 that surrounds and contacts a lower surface and a sidewall of the contact plug 374. Detailed configurations of the contact plug 374 and the conductive barrier pattern 376 may be respectively the same as described regarding the contact plug 174 and the conductive barrier pattern 176 with reference to FIGS. 2A and 3A.

The integrated circuit device 300 may include an insulating film 349 that covers an upper surface of each of the plurality of source/drain contacts CA3 and an upper surface of each of the plurality of insulating capping lines 340. Each of the plurality of source/drain contacts CA3 may pass through the insulating film 349 in the vertical direction (Z direction). In some example embodiments, the insulating film 349 may include, but is not limited to, a silicon oxide film.

As shown in FIGS. 7A and 7B, an upper surface of each of the insulating film 349 and the plurality of source/drain contacts CA3 may be covered by an upper insulating structure 380. The upper insulating structure 380 may include an etch stop film 382 and an interlayer dielectric 384, which are sequentially stacked in the stated order on the plurality of source/drain contacts CA3 and the insulating film 349. The etch stop film 382 and the interlayer dielectric 384 may respectively have the same configurations as the etch stop film 182 and the interlayer dielectric 184 described with reference to FIGS. 2A and 2B.

A plurality of via contacts VP3 may be respectively arranged on the plurality of source/drain contacts CA3. Each of the plurality of via contacts VP3 may be in contact with the source/drain contact CA3 through the upper insulating structure 380. Each of the plurality of via contacts VP3 may have the same configuration as the via contact VP1 described with reference to FIGS. 2A and 3A.

As shown in FIGS. 6 and 7A to 7C, a plurality of gate contacts CB3 may be respectively arranged on the plurality of gate lines GL. Each of the plurality of gate contacts CB3 may be in contact with the upper surface of the gate line GL through the upper insulating structure 380, the insulating film 349, and the insulating capping line 340. Each of the plurality of gate lines GL may be connected to a conductive line thereover through the gate contact CB3. A more detailed configuration of each of the plurality of gate contacts CB3 is the same as described regarding the gate contact CB with reference to FIGS. 2A, 2B, and 3B.

As shown in FIG. 6, in the logic cell LC, a ground line VSS may be connected to the fin-type active region FA in the first device area RX1 through the source/drain contact CA3 in the first device area RX1 from among the plurality of source/drain contacts CA3, and a power line VDD may be connected to the fin-type active region FA in the second device area RX2 through the source/drain contact CA3 in the second device area RX2 from among the plurality of source/drain contacts CA3. The ground line VSS and the power line VDD may be formed above or at a higher level than an upper surface of each of the plurality of source/drain contacts CA3 and the plurality of gate contacts CB3.

In the integrated circuit device 300 shown in FIGS. 6 and 7A to 7C, a constituent material of the via contact VP3 may have an electric resistance or resistivity less than an electric resistance or resistivity of a constituent material of the conductive barrier pattern 376. Because an upper portion of the sidewall of the contact plug 374 of the source/drain contact CA3 is covered by the via contact VP3 having an electric resistance or resistivity less than an electric resistance or resistivity of the conductive barrier pattern 376, contact resistance between the source/drain contact CA3 and the via contact VP3 may be reduced to improve electrical characteristics of the integrated circuit device 300. Alternatively or additionally, a constituent material of the gate contact CB3 may have an electric resistance or resistivity less than an electric resistance or resistivity of a constituent material of the second work function metal-containing film 364. Because an upper portion of the sidewall of the first work function metal-containing film 362 of the gate line GL is covered by the gate contact CB3 having an electric resistance less than an electric resistance of the second work function metal-containing film 364, contact resistance between the gate line GL and the gate contact CB3 may be reduced to improve the electrical characteristics (such as the speed and/or power consumption) of the integrated circuit device 300.

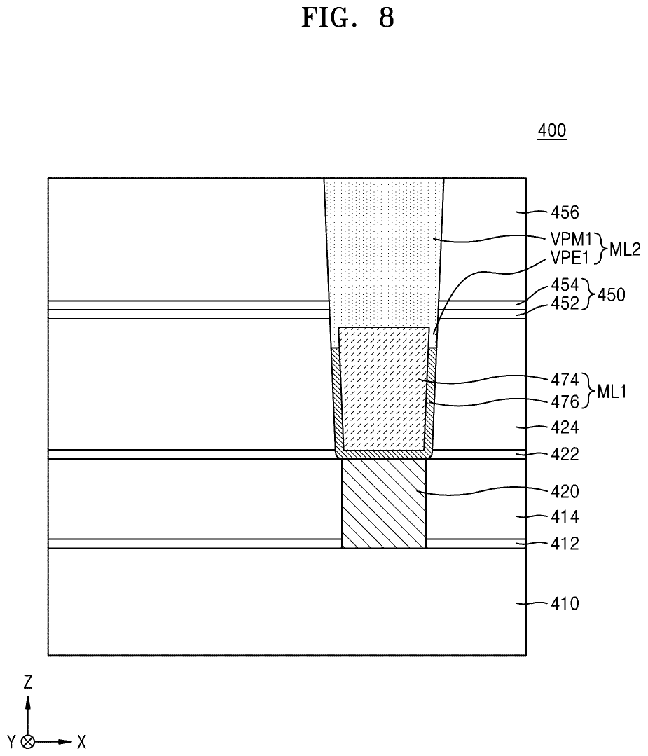

FIG. 8 is a cross-sectional view illustrating main components of an integrated circuit device 400 according to some example embodiments.

Referring to FIG. 8, the integrated circuit device 400 may include a lower structure 410. The lower structure 410 may include a semiconductor substrate including a semiconductor, such as Si and/or Ge, or a compound semiconductor, such as SiGe, SiC, GaAs, InAs, or InP. The lower structure 410 may include a conductive region (not shown). The conductive region may include an impurity-doped well, an impurity-doped structure, or a conductive layer. In some example embodiments, the lower structure 410 may include circuit elements (not shown), such as a gate structure, an impurity region, a contact plug, and the like. For example, the lower structure 410 may include at least some of the components of the integrated circuit devices 100, 200A, 200B, and 300 described with reference to FIGS. 1 and 2A to 7C.

A first etch stop film 412 and a lower insulating film 414 may be sequentially stacked in the stated order on the lower structure 410, and a lower wiring structure 420 may be arranged on the lower structure 410 to pass through the lower insulating film 414 and the first etch stop film 412.

The first etch stop film 412 may include a material having different etch selectivity from (e.g. slower than) the lower insulating film 414. In some example embodiments, the first etch stop film 412 may include a silicon nitride film, a carbon-doped silicon nitride film, or a carbon-doped silicon oxynitride film. Alternatively or additionally, in some example embodiments, the first etch stop film 412 may include a metal nitride film, for example, an AlN film. In some example embodiments, the lower insulating film 414 may include a silicon oxide film. For example, the lower insulating film 414 may include a silicon oxide-based material, such as one or more of plasma-enhanced oxide (PEOX), tetraethyl orthosilicate (TEOS), boro-TEOS (BTEOS), phosphorous TEOS (PTEOS), boro-phospho-TEOS (BPTEOS), boro-silicate glass (BSG), phosphor-silicate glass (PSG), or boro-phospho-silicate glass (BPSG). In some example embodiments, the lower insulating film 414 may include a low-K film having a low dielectric constant (that is, K) of about 2.2 to about 3.0, for example, an SiOC film and/or an SiCOH film. The lower wiring structure 420 may include a metal film and a conductive barrier film surrounding the metal film. The metal film may include one or more of Mo, Cu, W, Al, or Co. The conductive barrier film may include Ti, Ta, W, TiN, TaN, WN, WCN, TiSiN, TaSiN, WSiN, or a combination thereof. In some example embodiments, the lower wiring structure 420 may be electrically connected to the conductive region formed in the lower structure 410. In some example embodiments, the lower wiring structure 420 may be connected to a source/drain region (not shown) or a gate electrode (not shown) of a transistor formed in the lower structure 410.

A second etch stop film 422 and a first insulating film 424 may be arranged in the stated order on the lower insulating film 414. A first metal wiring structure ML1 may extend to the lower wiring structure 420 through an insulating structure including the first insulating film 424 and the second etch stop film 422.

The first metal wiring structure ML1 may include a contact plug 474 and a conductive barrier pattern 476. The conductive barrier pattern 476 may surround a portion of the contact plug 474 and cover a lower portion of a sidewall of the contact plug 474. Herein, the contact plug 474 may be referred to as a first conductive pattern, and the conductive barrier pattern 476 may be referred to as a second conductive pattern. More detailed configurations of the contact plug 474 and the conductive barrier pattern 476 are respectively the same as described regarding the contact plug 174 and the conductive barrier pattern 176 of the source/drain contact CA with reference to FIGS. 2A and 3A.

The integrated circuit device 400 may include an insulating capping layer 450, which covers an upper surface of each of the first metal wiring structure ML1 and the first insulating film 424. In some example embodiments, the insulating capping layer 450 may have a multilayered structure, which includes a first insulating capping layer 452 containing a metal and a second insulating capping layer 454 containing no metal. In some example embodiments, the first insulating capping layer 452 may include AlN, AlON, AlO, or AlOC, and the second insulating capping layer 454 may include silicon carbide (SiC), silicon nitride (SiN), nitrogen-doped silicon carbide (SiC:N), or SiOC, but example embodiments are not limited thereto. In some example embodiments, one of the first insulating capping layer 452 and the second insulating capping layer 454 may be omitted from the insulating capping layer 450.

The insulating capping layer 450 may be covered by a second insulating film 456. A second metal wiring structure ML2 may be connected to the first metal wiring structure ML1 through an insulating structure including the insulating capping layer 450 and the second insulating film 456. A constituent material of the second insulating film 456 is substantially the same as described regarding the lower insulating film 414.

The second metal wiring structure ML2 may include a main plug portion VPM1, which overlaps each of the contact plug 474 and the conductive barrier pattern 476 of the first metal wiring structure ML1 in the vertical direction (Z direction), and a vertical extension portion VPE1, which extends from a local region of the main plug portion VPM1 to the lower structure 410. The vertical extension portion VPE1 of the second metal wiring structure ML2 may cover an upper portion of the sidewall of the contact plug 474 and overlap the conductive barrier pattern 476 in the vertical direction (Z direction). The main plug portion VPM1 and the vertical extension portion VPE1 of the second metal wiring structure ML2 may be integrally connected to each other and may include the same material.

In the integrated circuit device 400 described with reference to FIG. 8, a constituent material of the second metal wiring structure ML2 may have an electric resistance or resistivity less than an electric resistance or resistivity of a constituent material of the conductive barrier pattern 476. Because the upper portion of the sidewall of the contact plug 474 of the first metal wiring structure ML1 is covered by the second metal wiring structure ML2 having an electric resistance less than an electric resistance of the conductive barrier pattern 476, contact resistance between the first metal wiring structure ML1 and the second metal wiring structure ML2 may be reduced to improve electrical characteristics of the integrated circuit device 400.

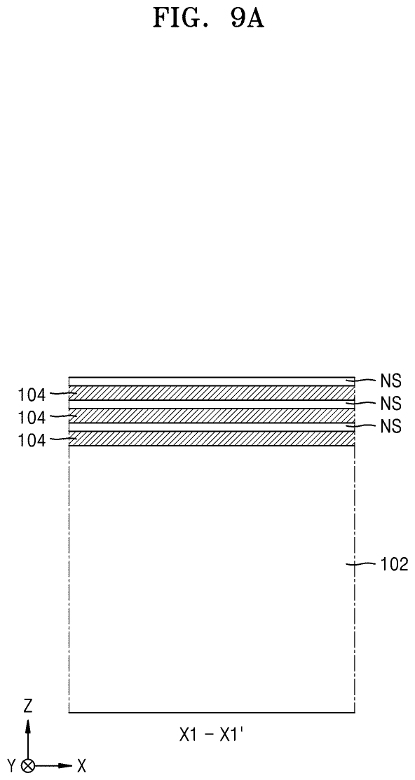

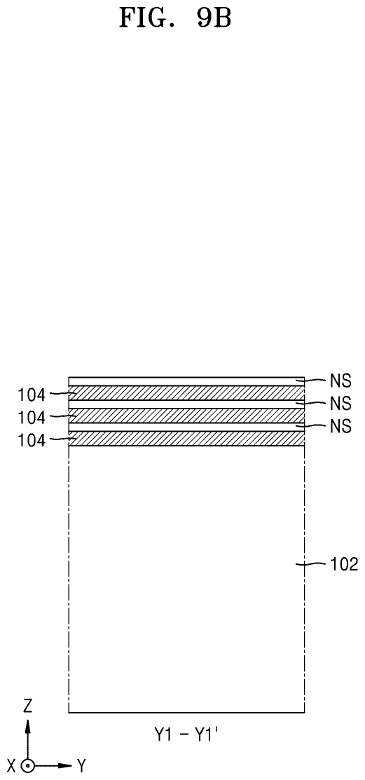

FIGS. 9A to 19 are cross-sectional views respectively illustrating a sequence of processes of a method of fabricating an integrated circuit device, according to some example embodiments. More specifically, FIGS. 9A, 10A, 11A, and 12 to 19 are cross-sectional views respectively illustrating examples of cross-sectional structures in a region corresponding to a cross-section taken along the line X1-X1′ of FIG. 1 according to the sequence of processes. FIGS. 9B, 10B, and 11B are cross-sectional views respectively illustrating examples of cross-sectional structures in a region corresponding to a cross-section taken along the line Y1-Y1′ of FIG. 1 according to the sequence of processes. An example of a method of fabricating the integrated circuit device 100 shown in FIGS. 1 and 2A to 3B is described with reference to FIGS. 9A to 19. In FIGS. 9A to 19, the same reference numerals as in FIGS. 1 and 2A to 3B respectively denote the same members, and here, repeated descriptions thereof are omitted.

Referring to FIGS. 9A and 9B, a plurality of sacrificial semiconductor layers 104 and a plurality of nanosheet semiconductor layers NS may be alternately stacked one by one on the substrate 102, for example with a process such as an atomic layer deposition (ALD) process. A thickness of each of the sacrificial semiconductor layers 104 may be the same as each other, or at least one of the sacrificial semiconductor layers 104 may have a thickness greater than or less than at least one other of the sacrificial semiconductor layers 104. A thickness of each of the nanosheet semiconductor layers NS may be the same as each other, or at least one of the of nanosheet semiconductor layers NS may have a thickness greater than or less than at least one other of the nanosheet semiconductor layers NS. A thickness of a nanosheet semiconductor layer NS may be the same as, greater than, or less than a thickness of a sacrificial semiconductor layer 104 below the nanosheet semiconductor layer NS.

The plurality of sacrificial semiconductor layers 104 and the plurality of nanosheet semiconductor layers NS may respectively include semiconductor materials having different etch selectivities from each other. In some example embodiments, the plurality of nanosheet semiconductor layers NS may each include an Si layer, and the plurality of sacrificial semiconductor layers 104 may each include a SiGe layer. In some example embodiments, the amount of Ge may be constant in the plurality of sacrificial semiconductor layers 104; however, example embodiments are not limited thereto. The SiGe layer constituting the plurality of sacrificial semiconductor layers 104 may include Ge in a constant amount selected from a range of about 5 at % to about 60 at %, for example, about 10 at % to about 40 at %. The amount of Ge in the SiGe layer, which constitutes the plurality of sacrificial semiconductor layers 104, may be variously selected as needed.

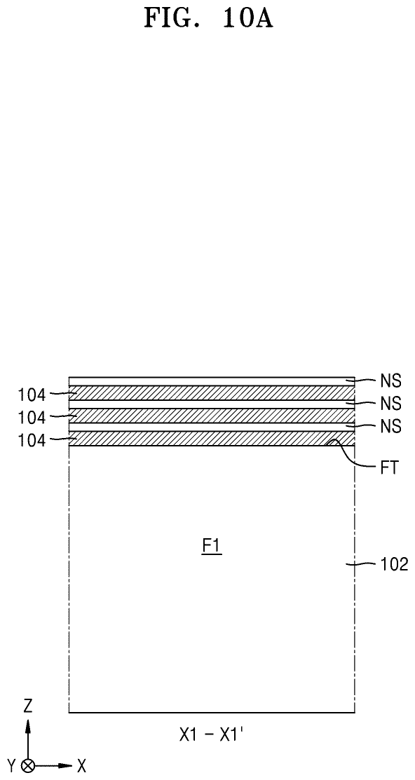

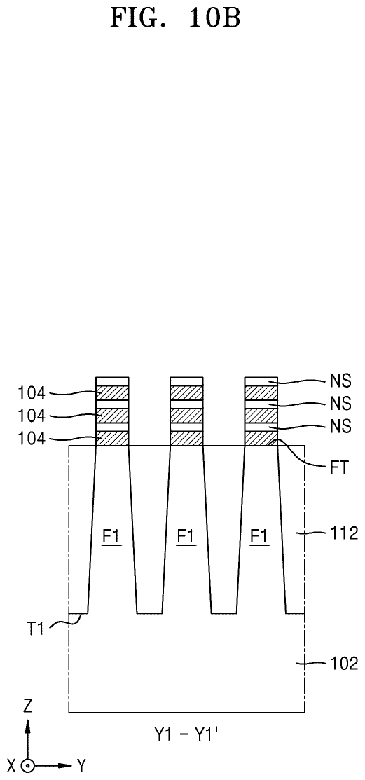

Referring to FIGS. 10A and 10B, the plurality of sacrificial semiconductor layers 104, the plurality of nanosheet semiconductor layers NS, and the substrate 102 may each be partially etched, thereby defining the plurality of fin-type active regions F1 in the substrate 102. Next, the device isolation film 112 may be formed, e.g. with a shallow trench isolation (STI) process, to cover a sidewall of each of the plurality of fin-type active regions F1. A stack structure of the plurality of sacrificial semiconductor layers 104 and the plurality of nanosheet semiconductor layers NS may remain on the fin top surface FT of each of the plurality of fin-type active regions F1.

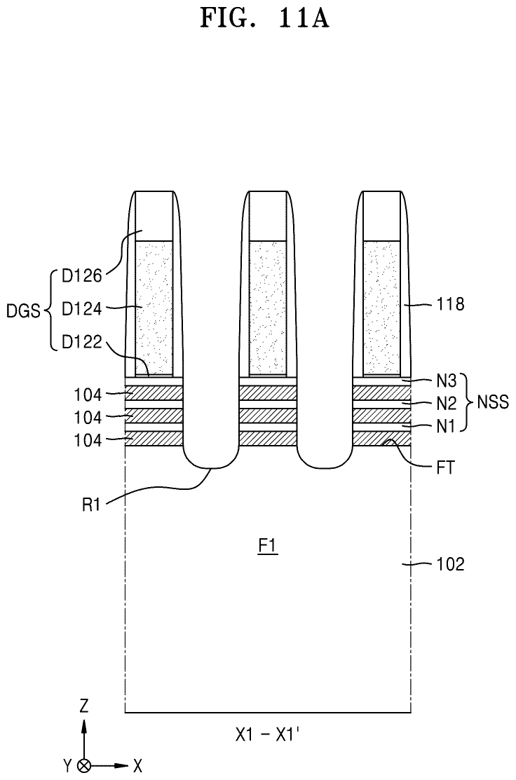

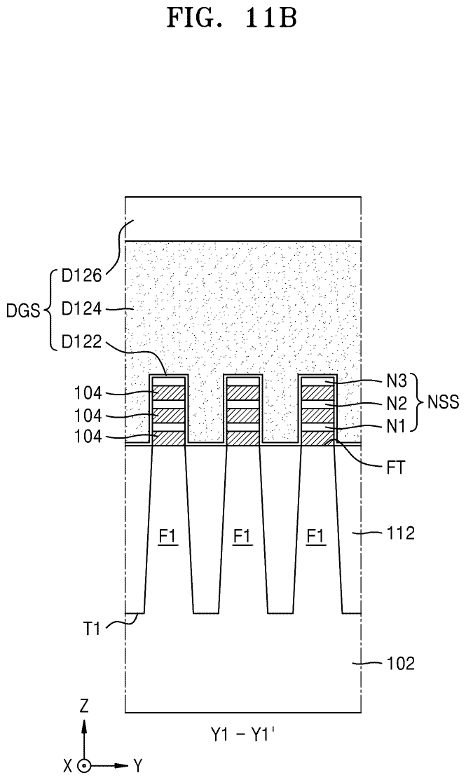

Referring to FIGS. 11A and 11B, a plurality of dummy gate structures DGS may be formed on the stack structure of the plurality of sacrificial semiconductor layers 104 and the plurality of nanosheet semiconductor layers NS.

Each of the plurality of dummy gate structures DGS may extend lengthwise in the second horizontal direction (Y direction). Each of the plurality of dummy gate structures DGS may have a structure in which an oxide film D122, a dummy gate layer D124, and a capping layer D126 are stacked in the stated order. In some example embodiments, the dummy gate layer D124 may include polysilicon such as doped or undoped polysilicon, and the capping layer D126 may include a silicon nitride film.

The plurality of outer insulating spacers 118 may be formed to cover both sidewalls of each of the plurality of dummy gate structures DGS, followed by etching a portion of each of the plurality of sacrificial semiconductor layers 104 and the plurality of nanosheet semiconductor layers NS and a portion of the fin-type active region F1 by using the plurality of dummy gate structures DGS and the plurality of outer insulating spacers 118 as an etch mask, thereby dividing the plurality of nanosheet semiconductor layers NS into the plurality of nanosheet stacks NSS and forming the plurality of recesses R1 in an upper portion of the fin-type active region F1. Each of the plurality of nanosheet stacks NSS may include the first nanosheet N1, the second nanosheet N2, and the third nanosheet N3. To form the plurality of recesses R1, etching may be performed by using dry etching, wet etching, or a combination thereof.

Referring to FIG. 12, in a resulting product of FIGS. 11A and 11B, the plurality of source/drain regions 130 may be formed to fill the plurality of recesses R1, respectively.

To form the plurality of source/drain regions 130, a semiconductor material may be deposited and/or grown, e.g. epitaxially grown on a surface of the fin-type active region F1, which is exposed at bottom surfaces of the plurality of recesses R1, and on the sidewall of each of the first nanosheet N1, the second nanosheet N2, and the third nanosheet N3, which are included in the nanosheet stack NSS. During the process of forming the fin-type active region F1, impurities may be incorporated and/or implanted into the fin-type active region F1; example embodiments are not limited thereto.

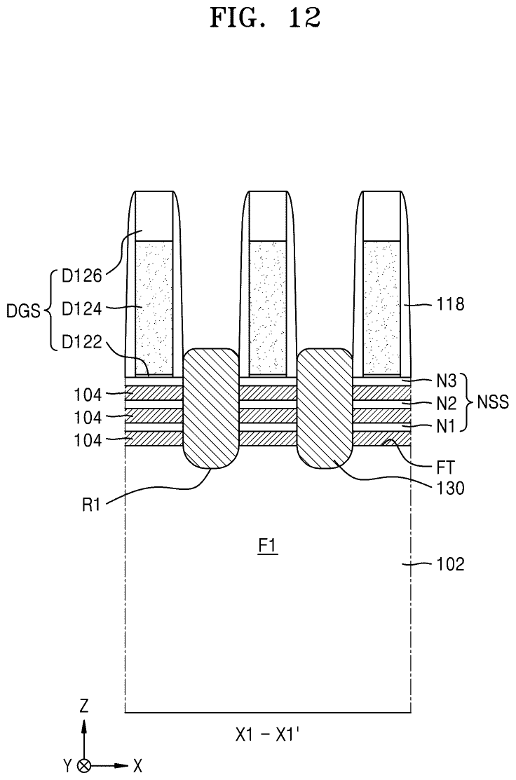

Referring to FIG. 13, the insulating liner 142 may be formed to cover a resulting product of FIG. 12, followed by forming the inter-gate dielectric 144 on the insulating liner 142, and then, an upper surface of the capping layer D126 may be exposed by partially etching each of the insulating liner 142 and the inter-gate dielectric 144. Next, the dummy gate layer D124 may be exposed by removing a plurality of capping layers D126, and the insulating liner 142 and the inter-gate dielectric 144 may be partially removed such that the upper surface of the inter-gate dielectric 144 is at a level approximately equal to that of the upper surface of the dummy gate layer D124.

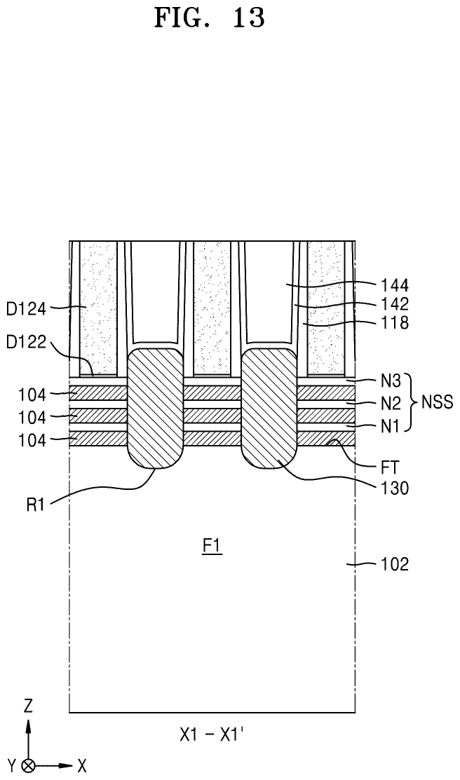

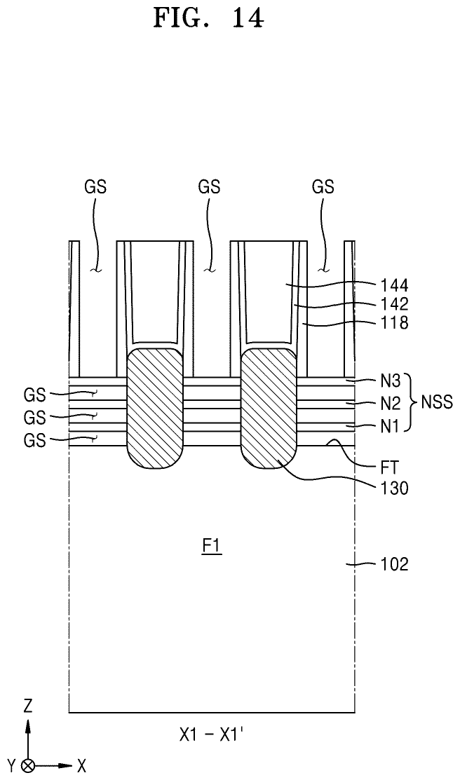

Referring to FIG. 14, a gate space GS may be provided by removing the dummy gate layer D124 and the oxide film D122 under the dummy gate layer D124 from a resulting product of FIG. 13, and the plurality of nanosheet stacks NSS may be exposed by the gate space GS. Next, by removing the plurality of sacrificial semiconductor layers 104, which remain on the fin-type active region F1, through the gate space GS, the gate space GS may expand up to spaces between the first nanosheet N1, the second nanosheet N2, and the third nanosheet N3 and a space between the first nanosheet N1 and the fin top surface FT of the fin-type active region F1. In some example embodiments, to selectively remove the plurality of sacrificial semiconductor layers 104, a difference in etch selectivity, such as a difference in wet etch selectivity and/or dry-etch selectivity, between the plurality of sacrificial semiconductor layers 104 and each of the first nanosheet N1, the second nanosheet N2, and the third nanosheet N3 may be used.

To selectively remove the plurality of sacrificial semiconductor layers 104, a liquid and/or gaseous etchant may be used. In some example embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but example embodiments are not limited thereto.

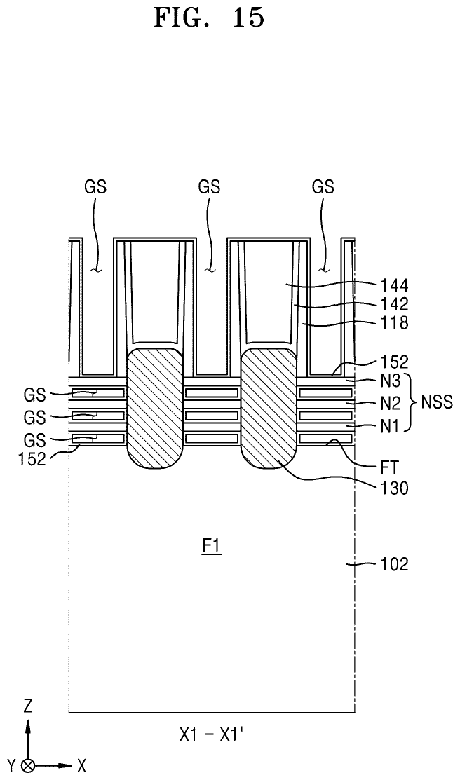

Referring to FIG. 15, in a resulting product of FIG. 14, the gate dielectric film 152 may be formed to cover respective exposed surfaces of the first nanosheet N1, the second nanosheet N2, the third nanosheet N3, and the fin-type active region F1. To form the gate dielectric film 152, thermal oxidation and/or an atomic layer deposition (ALD) process may be used.

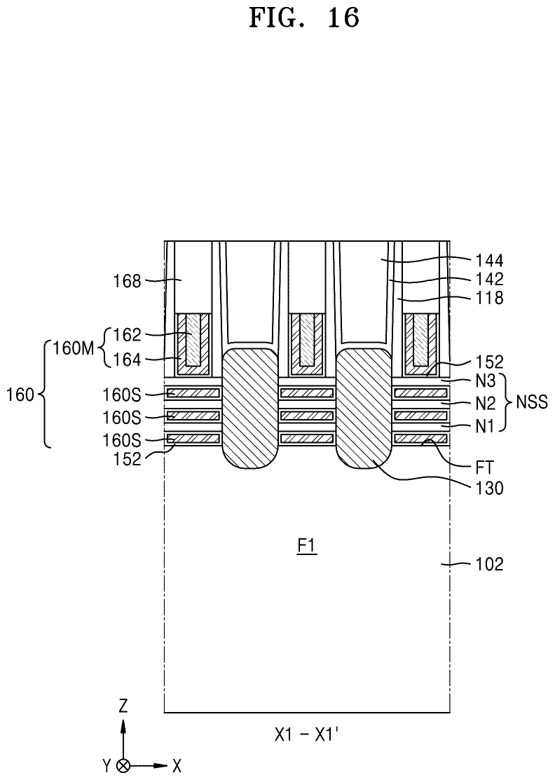

Referring to FIG. 16, the gate line 160 may be formed on the gate dielectric film 152 to fill the gate space GS (see FIG. 15) and cover the upper surface of the inter-gate dielectric 144, and then, the capping insulating pattern 168 may be formed in the gate space GS to cover the upper surface of each of the gate line 160 and the gate dielectric film 152.

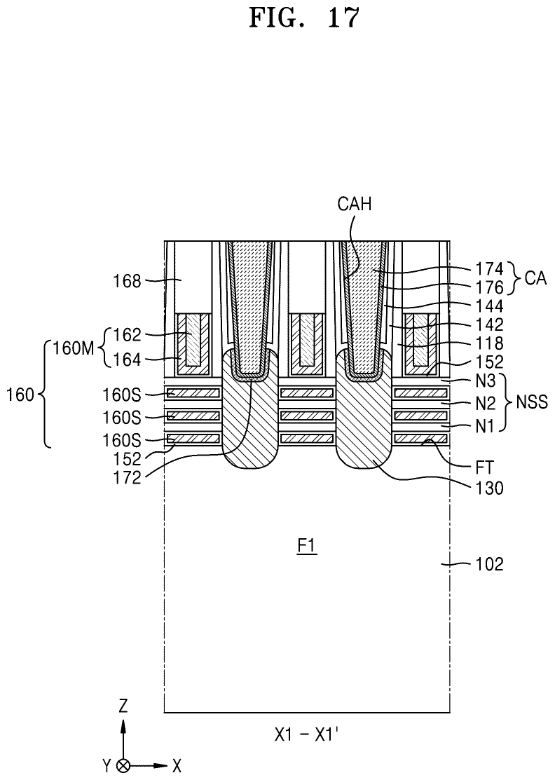

Referring to FIG. 17, in a resulting product of FIG. 16, a source/drain contact hole CAH may be formed to pass through an insulating structure including the insulating liner 142 and the inter-gate dielectric 144 to expose the source/drain region 130. A portion of the source/drain region 130 may be removed through the source/drain contact hole CAH by an anisotropic etching process, thereby causing the source/drain contact hole CAH to further extend toward the substrate 102. In some example embodiments, the anisotropic etching process for forming the source/drain contact hole CAH may be performed, for example, with a dry etching process, for example by using plasma.

After the source/drain contact hole CAH is formed, the metal silicide film 172 may be formed on the source/drain region 130 that is exposed at the bottom of the source/drain contact hole CAH. In some example embodiments, to form the metal silicide film 172, a process of forming or depositing a metal liner (not shown) to conformally cover an inner wall of the source/drain contact hole CAH and then inducing a reaction between the source/drain region 130 and a metal constituting the metal liner by performing heat treatment may be performed. After the metal silicide film 172 is formed, the remaining portion of the metal liner may be removed. During a process of forming the metal silicide film 172, a portion of the source/drain region 130 may be consumed. In some example embodiments, when the metal silicide film 172 includes a titanium silicide film, the metal liner may include a Ti film.

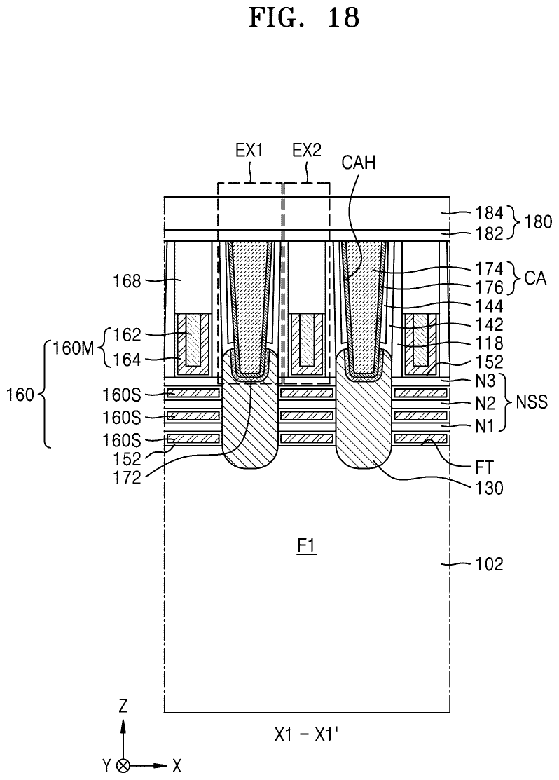

Referring to FIG. 18, in a resulting product of FIG. 17, the source/drain contact CA, which includes the conductive barrier pattern 176 and the contact plug 174, may be formed in each source/drain contact hole CAH.

Next, the etch stop film 182 and the interlayer dielectric 184 may be formed in the stated order to cover respective upper surfaces of the source/drain contact CA and the plurality of capping insulating patterns 168, thereby forming the upper insulating structure 180.

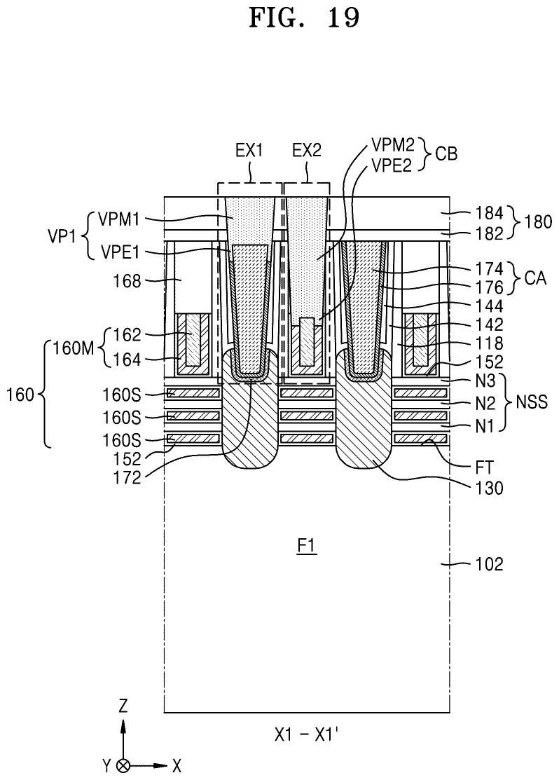

Referring to FIG. 19, in a resulting product of FIG. 18, the via contact VP1 may be formed to be connected to the source/drain contact CA, and the gate contact CB may be formed to be connected to the gate line 160.

In some example embodiments, the via contact VP1 and the gate contact CB may be simultaneously or concurrently formed. In some example embodiments, the via contact VP1 and the gate contact CB may be sequentially formed by separate processes, respectively. In this case, the via contact VP1 may be formed first, followed by forming the gate contact CB, or the gate contact CB may be formed first, followed by forming the via contact VP1.

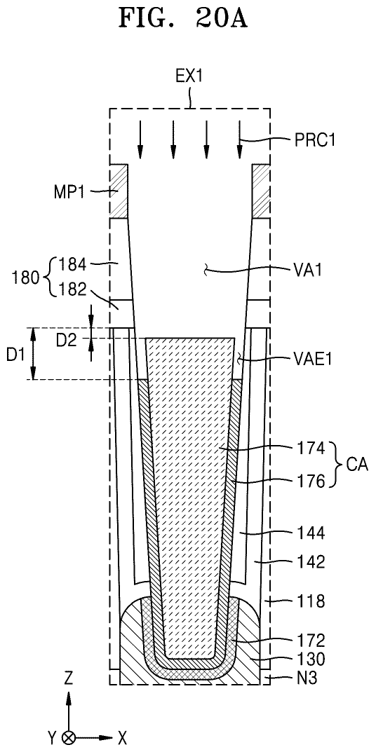

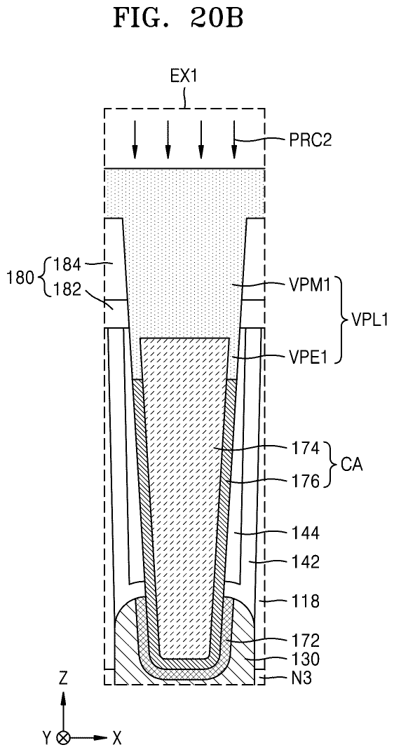

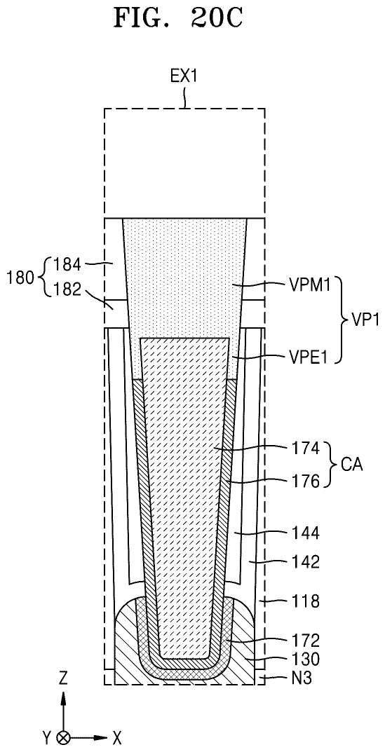

FIGS. 20A to 20C are cross-sectional views respectively illustrating a sequence of example processes of forming the via contact VP1 shown in FIGS. 2A, 3A, and 19. FIGS. 20A to 20C each illustrate an enlarged cross-sectional configuration of a region corresponding to the region EX1 of FIGS. 18 and 19.

Referring to FIG. 20A, in the resulting product of FIG. 18, a mask pattern MP1 may be formed on the upper insulating structure 180, and the via hole VA1 may be formed by etching the upper insulating structure 180 by using the mask pattern MP1 as an etch mask.

Next, a portion of the conductive barrier pattern 176, which is exposed by the via hole VA1, may be etched, thereby reducing the length of the conductive barrier pattern 176 in the vertical direction (Z direction).

In some example embodiments, to etch the portion of the conductive barrier pattern 176, a metal-containing etching gas PRC1 may be used. For example, when the conductive barrier pattern 176 includes a TiN film, the metal-containing etching gas PRC1 may include a halogen element-containing metal compound. H₂ gas may be further added to the metal-containing etching gas PRC1, as needed. A relative content ratio of each of the halogen element-containing metal compound and H₂ gas, which are included in the metal-containing etching gas PRC1, may be controlled, thereby controlling an etch rate of the conductive barrier pattern 176. In some example embodiments, the halogen element-containing metal compound may be selected from among, but is not limited to, MoCl₃, MoCl₅, MoOCl₄, MoCl₆, MoO₂Cl₂, MoOCl₄, WCl₆, WCl₅, and a combination thereof.

While the portion of the conductive barrier pattern 176 is etched, an exposed portion of the contact plug 174 adjacent to the conductive barrier pattern 176 may also be partially etched by an atmosphere of the metal-containing etching gas PRC1. As a result, after the portion of the conductive barrier pattern 176 is etched, the vertical level of the uppermost surface of the conductive barrier pattern 176, which is exposed by the via hole VA1, may be lower by the first vertical distance D1 than the vertical level of the uppermost surface of the at least one of the insulating liner 142 and the inter-gate dielectric 144. In some example embodiments, the vertical level of the uppermost surface of the contact plug 174, which is exposed by the via hole VA1, may be lower by the second vertical distance D2 than the uppermost surface of the at least one of the insulating liner 142 and the inter-gate dielectric 144. The first vertical distance D1 may be greater than the second vertical distance D2.

In some example embodiments, an etching gas used in an etch-back process of the conductive barrier pattern 176 may include the same compound as a metal precursor used in a subsequent deposition process for forming the via contact VP1. For example, when the via contact VP1 formed in the subsequent process includes Mo, the etching gas used in the etch-back process of the conductive barrier pattern 176 may include an Mo-containing compound, for example, MoCb, MoCl₅, MoOCl₄, MoCl₆, MoO₂Cl₂, MoOCl₄, or a combination thereof.

In some example embodiments, the etch-back process of the conductive barrier pattern 176 may be performed at a first temperature selected from a range of about 400° C. to about 450° C. While the etch-back process of the conductive barrier pattern 176 is performed, as a portion of the conductive barrier pattern 176 and a portion of the contact plug 174 are removed through the via hole VA1, the via hole VA1 may expand in the vertical direction (Z direction).

Referring to FIG. 20B, in a resulting product of FIG. 20A, a via contact layer VPL1 may be formed to fill the via hole VA1 on the contact plug 174 and the conductive barrier pattern 176 of the source/drain contact CA. The via contact layer VPL1 may include the main plug portion VPM1, which overlaps each of the contact plug 174 and the conductive barrier pattern 176 of the source/drain contact CA in the vertical direction (Z direction), and the vertical extension portion VPE1, which extends from a local region of the main plug portion VPM1 toward the substrate 102.

The via contact layer VPL1 may include a metal film. To form the via contact layer VPL1, a metal precursor PRC2 may be used. In some example embodiments, the via contact layer VPL1 may include molybdenum (Mo) or tungsten (W). For example, the via contact layer VPL1 may include an Mo film. In this case, to form the via contact layer VPL1, an ALD or chemical vapor deposition (CVD) process using an Mo precursor may be performed. When the via contact layer VPL1 includes the Mo film, the Mo precursor may be selected from among MoCb, MoCl₅, MoOCl₄, MoCl₆, Mo(CO)₆, MoO₂Cl₂, MoOCl₄, MoF₆, an organic Mo compound, and a combination thereof. In some example embodiments, the organic Mo compound may be selected from among molybdenum acetylacetonate, biscyclopentadienyl molybdenum dihydride, bismethylcyclopentadienyl molybdenum dihydride, bisethylcyclopentadienyl molybdenum dihydride, bisisopropylcyclopentadienyl molybdenum dihydride, biscyclopentadienyl imide molybdenum, and a combination thereof. However, the Mo precursor that may be used to form the via contact layer VPL1 is not limited to the examples set forth above.

In some example embodiments, the metal precursor PRC2 used in a process of forming the via contact layer VPL1, and a metal compound in the metal-containing etching gas PRC1 used in etching of the conductive barrier pattern 176, which is described with reference to FIG. 20A, may include the same compound. For example, the metal precursor PRC2 used in the process of forming the via contact layer VPL1, and the metal compound in the metal-containing etching gas PRC1 used in etching of the conductive barrier pattern 176, which is described with reference to FIG. 20A, may include one or more of MoCb, MoCl₅, MoCl₆, or the like. In this case, the etching process of the conductive barrier pattern 176, which is described with reference to FIG. 20A, and the deposition process for forming the via contact layer VPL1, which is described with reference to FIG. 20B, may be performed in-situ in one chamber. In some example embodiments, while the etching process of the conductive barrier pattern 176, which is described with reference to FIG. 20A, and the deposition process for forming the via contact layer VPL1, which is described with reference to FIG. 20B, are performed in-situ, the same metal compound may be consecutively supplied into the one chamber. In addition, after the etching process of the conductive barrier pattern 176 in the chamber is finished, H₂ gas may be additionally supplied into the chamber at the time when the deposition process for forming the via contact layer VPL1 is performed.

In some example embodiments, when the etching process of the conductive barrier pattern 176, which is described with reference to FIG. 20A, and the deposition process for forming the via contact layer VPL1, which is described with reference to FIG. 20B, are performed in-situ, the etch-back process of the conductive barrier pattern 176 may be performed at a first temperature selected from a range of about 400° C. to about 450° C., and the process of forming the via contact layer VPL1 may be performed at a second temperature that is selected from the range of about 400° C. to about 450° C., and/or may be higher than the first temperature.

Referring to FIG. 20C, in a resulting product of FIG. 20B, a portion of the via contact layer VPL1, which is outside the via hole VA1, may be removed by a chemical mechanical polishing (CMP) process and/or an etch-back process, thereby exposing the upper surface of the interlayer dielectric 184. As a result, the via contact VP1 may be obtained from the via contact layer VPL1.

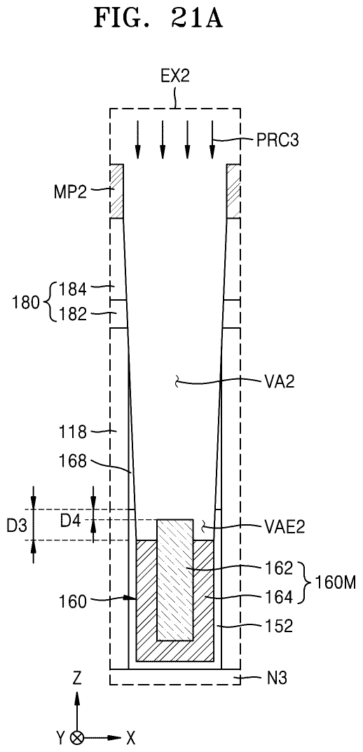

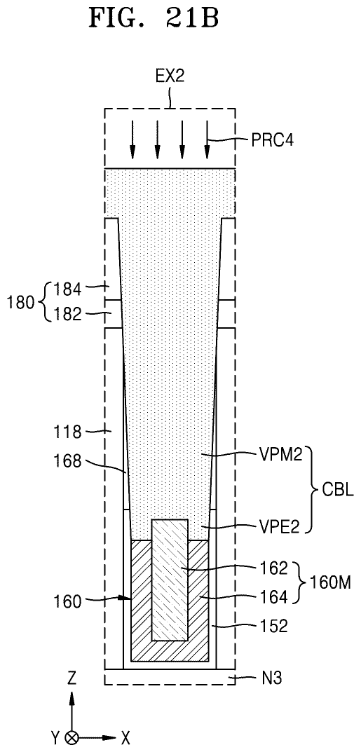

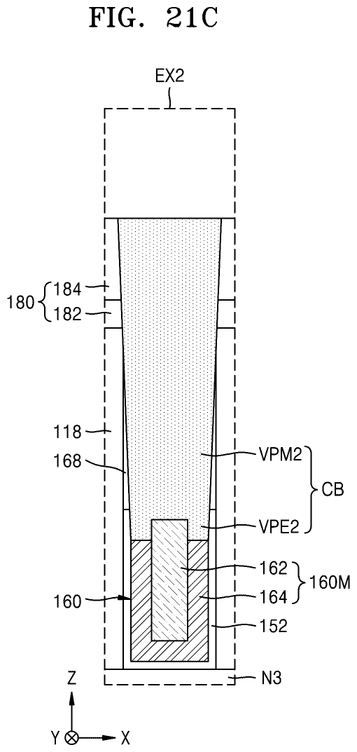

FIGS. 21A to 21C are cross-sectional views respectively illustrating a sequence of example processes of forming the gate contact CB shown in FIGS. 2A, 2B, 3B, and 19. FIGS. 21A to 21C each illustrate an enlarged cross-sectional configuration of a region corresponding to the region EX2 of FIGS. 18 and 19.

Referring to FIG. 21A, in the resulting product of FIG. 18, a mask pattern MP2 may be formed on the upper insulating structure 180, and the gate contact hole VA2 may be formed by etching the upper insulating structure 180 by using the mask pattern MP2 as an etch mask. The mask pattern MP2 may be the same as or different from the mask pattern MP1 shown in FIG. 20A.

Next, a portion of the second work function metal-containing film 164, which is exposed by the gate contact hole VA2, may be etched, thereby reducing the length of the second work function metal-containing film 164 in the vertical direction (Z direction).

In some example embodiments, to etch the portion of the second work function metal-containing film 164, a metal-containing etching gas PRC3 may be used. For example, when the second work function metal-containing film 164 includes a TiAlC film, the metal-containing etching gas PRC3 may include a halogen element-containing metal compound. H₂ gas may be further added to the metal-containing etching gas PRC3, as needed or desired. A relative content ratio of each of the halogen element-containing metal compound and H₂ gas, which are included in the metal-containing etching gas PRC3, may be controlled, thereby controlling an etch rate of the second work function metal-containing film 164. A more detailed configuration of the halogen element-containing metal compound is the same as described with reference to FIG. 20A.

While the portion of the second work function metal-containing film 164 is etched, an exposed portion of the first work function metal-containing film 162 adjacent to the second work function metal-containing film 164 may be partially etched by an atmosphere of the metal-containing etching gas PRC3. As a result, after the portion of the second work function metal-containing film 164 is etched, the vertical level of the uppermost surface of the first work function metal-containing film 162, which is exposed by the gate contact hole VA2, may be lower by the third vertical distance D3 than the vertical level of the uppermost surface of the gate dielectric film 152. In some example embodiments, the vertical level of the uppermost surface of the first work function metal-containing film 162, which is exposed by the gate contact hole VA2, may be lower by the fourth vertical distance D4 than the uppermost surface of the gate dielectric film 152. The third vertical distance D3 may be greater than the fourth vertical distance D4.

In some example embodiments, an etching gas used in an etch-back process (e.g. a blanket etch-back process) of the second work function metal-containing film 164 may include the same compound as a metal precursor used in a subsequent deposition process for forming the gate contact CB. For example, when the gate contact CB formed in the subsequent process includes Mo, the etching gas used in the etch-back process of the second work function metal-containing film 164 may include an Mo-containing compound, for example, MoCl₃, MoCl₅, MoOCl₄, MoCl₆, MoO₂Cl₂, MoOCl₄, or a combination thereof.

In some example embodiments, the etch-back process of the second work function metal-containing film 164 may be performed at a third temperature selected from a range of about 400° C. to about 450° C. While the etch-back process of the second work function metal-containing film 164 is performed, as a portion of the second work function metal-containing film 164 and a portion of the first work function metal-containing film 162 are removed through the gate contact hole VA2, the gate contact hole VA2 may expand in the vertical direction (Z direction).

Referring to FIG. 21B, in a resulting product of FIG. 21A, a gate contact layer CBL may be formed to fill the gate contact hole VA2 on the first work function metal-containing film 162 and the second work function metal-containing film 164 of the gate line 160. The gate contact layer CBL may include the main plug portion VPM2, which overlaps each of the first work function metal-containing film 162 and the second work function metal-containing film 164 of the gate line 160 in the vertical direction (Z direction), and a vertical extension portion VPE2, which extends from a local region of the main plug portion VPM2 toward the substrate 102.

The gate contact layer CBL may include a metal film. To form the gate contact layer CBL, a metal precursor PRC4 may be used. In some example embodiments, the gate contact layer CBL may include molybdenum (Mo) and/or tungsten (W). For example, the gate contact layer CBL may include an Mo film. In this case, to form the gate contact layer CBL, an ALD and/or a CVD process using an Mo precursor may be performed. When the gate contact layer CBL includes the Mo film, the Mo precursor may be one or more selected from among MoCl₃, MoCl₅, MoOCl₄, MoCl₆, Mo(CO)₆, MoO₂Cl₂, MoOCl₄, MoF₆, an organic Mo compound, and a combination thereof. A more detailed configuration of the Mo precursor is the same as described with reference to FIG. 20B.

In some example embodiments, the metal precursor PRC4 used in a process of forming the gate contact layer CBL, and a metal compound in the metal-containing etching gas PRC3 used in etching of the second work function metal-containing film 164, which is described with reference to FIG. 21A, may include (or be) the same compound. For example, the metal precursor PRC4 used in the process of forming the gate contact layer CBL, and the metal compound in the metal-containing etching gas PRC3 used in etching of the second work function metal-containing film 164, which is described with reference to FIG. 21A, may include one or more of MoCb, MoCl₅, MoCl₆, or the like. In this case, the etching process of the second work function metal-containing film 164, which is described with reference to FIG. 21A, and the deposition process for forming the gate contact layer CBL, which is described with reference to FIG. 21B, may be performed in-situ in one chamber. In some example embodiments, while the etching process of the second work function metal-containing film 164, which is described with reference to FIG. 21A, and the deposition process for forming the gate contact layer CBL, which is described with reference to FIG. 21B, are performed in-situ, the same metal compound may be consecutively supplied into the one chamber. Alternatively or additionally, after the etching process of the second work function metal-containing film 164 in the chamber is finished, H₂ gas may be additionally supplied into the chamber at the time when the deposition process for forming the gate contact layer CBL is performed.

In some example embodiments, when the etching process of the second work function metal-containing film 164, which is described with reference to FIG. 21A, and the deposition process for forming the gate contact layer CBL, which is described with reference to FIG. 21B, are performed in-situ, the etch-back process of the second work function metal-containing film 164 may be performed at a third temperature selected from a range of about 400° C. to about 450° C., and the process of forming the gate contact layer CBL may be performed at a fourth temperature that is selected from the range of about 400° C. to about 450° C., and may be higher than the third temperature.

Referring to FIG. 21C, in a resulting product of FIG. 21B, a portion of the gate contact layer CBL, which is outside the gate contact hole VA2, may be removed by a CMP process, thereby exposing the upper surface of the interlayer dielectric 184. As a result, the gate contact CB may be obtained from the gate contact layer CBL.

Heretofore, while the example of the method of fabricating the integrated circuit device 100 shown in FIGS. 1 and 2A to 3B has been described with reference to FIGS. 9A to 21C, it will nay be understood by those of ordinary skill in the art that, by making various modifications and changes to the example described with reference to FIGS. 9A to 21C without departing from the spirit and scope of inventive concepts, the integrated circuit devices 200A, 200B, 300, and 400 shown in FIGS. 4 to 8 and integrated circuit devices having various structures modified and changed therefrom may be fabricated.

While various example embodiments have been particularly shown and described with reference to embodiments thereof, it will be understood that various changes in form and details may be made therein without departing from the spirit and scope of the following claims. Furthermore, example embodiments are not necessarily mutually exclusive with one another. For example, some example embodiments may include one or more features described with reference to one or more figures, and may include one or more other features described with reference to one or more other figures.

What is claimed is:

1. An integrated circuit device comprising:
a first conductive pattern on a substrate;
a second conductive pattern surrounding at least a portion of the first conductive pattern and covering a lower portion of a sidewall of the first conductive pattern;
an upper insulating structure on the first conductive pattern and the second conductive pattern; and
an upper conductive pattern extending in a vertical direction through the upper insulating structure,
wherein the upper conductive pattern comprises:
a main plug portion overlapping the first conductive pattern and the second conductive pattern in the vertical direction; and
a vertical extension portion extending from a local region of the main plug portion toward the substrate, the vertical extension portion covering an upper portion of the sidewall of the first conductive pattern and overlapping the second conductive pattern in the vertical direction.

2. The integrated circuit device of claim 1, wherein
the first conductive pattern comprises a top portion protruding more than the second conductive pattern in a direction away from the substrate, and
the top portion of the first conductive pattern is in a space defined by the vertical extension portion.

3. The integrated circuit device of claim 1, wherein a constituent material of the upper conductive pattern has a resistivity less than a resistivity of a constituent material of the second conductive pattern.

4. The integrated circuit device of claim 1, wherein in the vertical direction a first length from the substrate to an uppermost surface of the first conductive pattern is greater than a second length from the substrate to an uppermost surface of the second conductive pattern.

5. The integrated circuit device of claim 1, further comprising:
a source/drain region between the substrate and the first conductive pattern,
wherein the first conductive pattern and the second conductive pattern are each electrically connected to the source/drain region.

6. The integrated circuit device of claim 1, further comprising:
a source/drain region between the substrate and the first conductive pattern, wherein the first conductive pattern comprises a material selected from among molybdenum (Mo), copper (Cu), tungsten (W), cobalt (Co), ruthenium (Ru), manganese (Mn), titanium (Ti), tantalum (Ta), aluminum (Al), and a combination thereof, and
the second conductive pattern comprises a metal nitride.

7. The integrated circuit device of claim 1, wherein in the vertical direction a length of the second conductive pattern is less than a length of the first conductive pattern.

8. The integrated circuit device of claim 1, further comprising:
a channel region between the substrate and the second conductive pattern; and
a gate dielectric film between the channel region and the second conductive pattern,
wherein the first conductive pattern is apart from the channel region with the gate dielectric film and the second conductive pattern between the first conductive pattern and the channel region.

9. The integrated circuit device of claim 1, further comprising:
a channel region between the substrate and the second conductive pattern,
wherein the first conductive pattern comprises TiN, and
the second conductive pattern comprises TiAlC.

10. The integrated circuit device of claim 1, wherein the upper conductive pattern is in contact with at least a portion of each of the first conductive pattern and the second conductive pattern.

11. The integrated circuit device of claim 1, wherein the upper conductive pattern comprises at least one of molybdenum (Mo) or tungsten (W).

12. An integrated circuit device comprising:
a fin-type active region protruding upward from a substrate;
a source/drain region on the fin-type active region;
a gate line on the fin-type active region and extending in a direction intersecting the fin-type active region;
an insulating structure on the source/drain region;
a source/drain contact passing through the insulating structure in a vertical direction and connected to the source/drain region;
an upper insulating structure on each of the source/drain contact and the gate line;
a first upper conductive pattern passing through the upper insulating structure in the vertical direction and connected to the source/drain contact; and
a second upper conductive pattern passing through the upper insulating structure in the vertical direction and connected to the gate line,
wherein at least one of the source/drain contact and the gate line comprises a first conductive pattern and a second conductive pattern, the second conductive pattern surrounding a at least a portion of the first conductive pattern and covering a lower portion of a sidewall of the first conductive pattern,
and at least one of the first upper conductive pattern and the second upper conductive pattern comprises:
a main plug portion overlapping the first conductive pattern and the second conductive pattern in the vertical direction; and
a vertical extension portion extending from a local region of the main plug portion toward the substrate, the vertical extension portion covering an upper portion of the sidewall of the first conductive pattern and overlapping the second conductive pattern in the vertical direction.

13. The integrated circuit device of claim 12, wherein a constituent material of each of the first upper conductive pattern and the second upper conductive pattern has a resistivity less than a resistivity of a constituent material of the second conductive pattern.

14. The integrated circuit device of claim 12, wherein
the first upper conductive pattern comprises the main plug portion and the vertical extension portion,
the main plug portion and the vertical extension portion are integrally connected to each other and comprise the same material,
the first conductive pattern comprises a material selected from among molybdenum (Mo), copper (Cu), tungsten (W), cobalt (Co), ruthenium (Ru), manganese (Mn), titanium (Ti), tantalum (Ta), aluminum (Al), and a combination thereof,
the second conductive pattern comprises a metal nitride, and
the first upper conductive pattern comprises molybdenum (Mo) or tungsten (W).

15. The integrated circuit device of claim 12, wherein
the second upper conductive pattern comprises the main plug portion and the vertical extension portion,
the main plug portion and the vertical extension portion are integrally connected to each other and comprise the same material,
the first conductive pattern comprises TiN,
the second conductive pattern comprises TiAlC, and
the second upper conductive pattern comprises molybdenum (Mo) or tungsten (W).

16. The integrated circuit device of claim 12, further comprising:
at least one nanosheet between the fin-type active region and the gate line and surrounded by the gate line.

17. An integrated circuit device comprising:
a fin-type active region on a substrate and extending lengthwise in a first horizontal direction;
at least one nanosheet over the fin-type active region;
a source/drain region facing the at least one nanosheet in the first horizontal direction;
a gate line on the fin-type active region, surrounding the at least one nanosheet and extending lengthwise in a second horizontal direction that intersects the first horizontal direction;
a source/drain contact connected to the source/drain region;
a via contact connected to the source/drain contact; and
a gate contact connected to the gate line,
wherein the source/drain contact comprises a contact plug and a conductive barrier pattern that surrounds a portion of the contact plug and covers a lower portion of a sidewall of the contact plug,
and the via contact comprises: a first main plug portion overlapping the contact plug and the conductive barrier pattern in a vertical direction; and a first vertical extension portion extending from a local region of the first main plug portion toward the substrate, the first vertical extension portion covering an upper portion of the sidewall of the contact plug and overlapping the conductive barrier pattern in the vertical direction.

18. The integrated circuit device of claim 17, wherein,
in the source/drain contact, a length of the conductive barrier pattern in the vertical direction is less than a length of the contact plug in the vertical direction,
the first vertical extension portion of the via contact is in contact with an upper surface of the conductive barrier pattern, and
a constituent material of the via contact has a resistivity less than a resistivity of a constituent material of the conductive barrier pattern.

19. The integrated circuit device of claim 17, wherein the gate line comprises: a first work function metal-containing film, which comprises a portion arranged above the at least one nanosheet; and a second work function metal-containing film, which surrounds a portion of the first work function metal-containing film and covers a lower portion of a sidewall of the first work function metal-containing film, and
the gate contact comprises: a second main plug portion overlapping the first work function metal-containing film and the second work function metal-containing film in the vertical direction; and a second vertical extension portion extending from a local region of the second main plug portion toward the substrate, the second vertical extension portion covering an upper portion of the sidewall of the first work function metal-containing film and overlapping the second work function metal-containing film in the vertical direction.

20. The integrated circuit device of claim 19, wherein,
over the at least one nanosheet, the length of the second work function metal-containing film in the vertical direction is less than the length of the first work function metal-containing film in the vertical direction,
the second vertical extension portion of the gate contact is in contact with an upper surface of the second work function metal-containing film, and
a constituent material of the gate contact has a resistivity less than a resistivity of a constituent material of the second work function metal-containing film.
